(19) United States
(12) Patent Application Publication
(10) Pub. No.: US 2026/0053040 A1
(43) Pub. Date: Feb. 19, 2026

(54) ELECTRONIC DEVICE AND METHOD FOR MANUFACTURING THE SAME

(71) Applicant: InnoLux Corporation, Miao-Li County (TW)

(72) Inventors: Yu-Ting TSAI, Miao-Li County (TW); Wei-Ju LIAO, Miao-Li County (TW); Yu-Tsung LIU, Miao-Li County (TW); I-An YAO, Miao-Li County (TW)

(21) Appl. No.: 19/269,370

(22) Filed: Jul. 15, 2025

(30) Foreign Application Priority Data
Aug. 13, 2024 (CN) 202411106024.5

(51) Int. Cl. H01L 23/00; H01L 25/065

(52) U.S. Cl. CPC H01L 24/05; H01L 24/06; H01L 24/28; H01L 24/32; H01L 24/83; H01L 25/0657; H01L 24/94; H01L 24/97; H01L 2224/05553; H01L 2224/05644; H01L 2224/05664; H01L 2224/0603; H01L 2224/06051; H01L 2224/29111; H01L 2224/32013; H01L 2224/32148; H01L 2224/83002; H01L 2224/83815; H01L 2224/94; H01L 2224/97

(57) ABSTRACT

An electronic device includes: a first substrate; an element layer disposed on the first substrate and including an active area and a peripheral area surrounding the active area; a first bonding pad disposed on the peripheral area of the element layer; a second substrate disposed opposite to the first substrate; a second bonding pad disposed on the second substrate and including a first part and a second part surrounding the first part; and a bonding material disposed between the first part of the second bonding pad and the first bonding pad and between the second part of the second bonding pad and the first bonding pad.

### CROSS-REFERENCE TO RELATED APPLICATIONS

This application claims the benefits of the Chinese Patent Application Serial Number 202411106024.5, filed on Aug. 13, 2024, the subject matter of which is incorporated herein by reference.

### BACKGROUND

### Field

The present disclosure relates to an electronic device and a method for manufacturing the same. More specifically, the present disclosure relates to an electronic device comprising an upper substrate and a bottom substrate and a method for manufacturing the same.

### Description of Related Art

Generally, in the manufacturing process of an electronic device, such as in the packaging process, an upper substrate and a bottom substrate are assembled and then cut into a plurality of independent electronic devices. In traditional manufacturing processes, bonding materials are often used to implement the step of assembling the upper substrate and the bottom substrate.

However, the conventional manufacturing process still has problems such as low sealing, poor vacuum degree or low packaging error tolerance after assembly, which results in poor reliability or high production cost of the electronic device.

Therefore, it is desirable to provide an electronic device and a method for manufacturing the same to solve the conventional defects.

### SUMMARY

The present disclosure provides an electronic device, comprising: a first substrate; an element layer disposed on the first substrate and comprising an active area and a peripheral area surrounding the active area; a first bonding pad disposed on the peripheral area of the element layer; a second substrate disposed opposite to the first substrate; a second bonding pad disposed on the second substrate and comprising a first part and a second part surrounding the first part; and a bonding material disposed between the first part of the second bonding pad and the first bonding pad and between the second part of the second bonding pad and the first bonding pad.

The present disclosure further provides a method for manufacturing an electronic device, comprising the following steps: providing a mother substrate; forming an element layer on the mother substrate, wherein the element layer comprises a plurality of active areas and a plurality of peripheral areas respectively surrounding the plurality of active areas; forming a plurality of first bonding pads on the plurality of peripheral areas of the element layer; providing a plurality of second substrates; forming a plurality of second bonding pads on the plurality of second substrates, wherein each of the plurality of second bonding pads respectively comprises a first part and a second part surrounding the first part; disposing the plurality of second substrates on the element layer to make the plurality of second bonding pads and the plurality of first bonding pads overlapped, and applying a bonding material on two adjacent first bonding pads of the plurality of the first bonding pads; and heating the bonding material, wherein the bonding material melts and diffuses between the first parts of the plurality of the second bonding pads and the plurality of first bonding pads and between the second parts of the plurality of second bonding pads and the plurality of first bonding pads.

Other novel features of the disclosure will become more apparent from the following detailed description when taken in conjunction with the accompanying drawings.

### BRIEF DESCRIPTION OF DRAWINGS

FIG. 1A to FIG. 1E are schematic views showing a method for manufacturing an electronic device according to one embodiment of the present disclosure.

FIG. 2 is a cross-sectional schematic view showing an electronic device according to one embodiment of the present disclosure.

FIG. 3A to FIG. 3C are schematic views showing a method for manufacturing an electronic device according to one embodiment of the present disclosure.

FIG. 3D is a partial enlarged view of FIG. 3C.

FIG. 4A and FIG. 4B are schematic views showing a method for manufacturing an electronic device according to one embodiment of the present disclosure.

FIG. 5A to FIG. 5D are schematic views showing a method for manufacturing an electronic device according to one embodiment of the present disclosure.

FIG. 6A to FIG. 6C are schematic views showing a method for manufacturing an electronic device according to one embodiment of the present disclosure.

FIG. 7A and FIG. 7B are schematic views showing a method for manufacturing an electronic device according to one embodiment of the present disclosure.

FIG. 8A to FIG. 8F are schematic views showing a method for manufacturing an electronic device according to one embodiment of the present disclosure.

### DETAILED DESCRIPTION

The following is specific embodiments to illustrate the implementation of the present disclosure. Those who are familiar with this technique can easily understand the other advantages and effects of the present disclosure from the content disclosed in the present specification. The present disclosure can also be implemented or applied by other different specific embodiments, and various details in the present specification can also be modified and changed according to different viewpoints and applications without departing from the spirit of the present disclosure.

It should be noted that, in the present specification, when a component is described to have an element, it means that the component may have one or more of the elements, and it does not mean that the component has only one of the element, except otherwise specified. Furthermore, the ordinals recited in the specification and the claims such as “first”, “second” and so on are intended only to describe the elements claimed and imply or represent neither that the claimed elements have any proceeding ordinals, nor that sequence between one claimed element and another claimed element or between steps of a manufacturing method. The use of these ordinals is merely to differentiate one claimed element having a certain designation from another claimed element having the same designation.

In the specification and the appended claims of the present disclosure, certain words are used to refer to specific elements. Those skilled in the art should understand that electronic device manufacturers may refer to the same components by different names. The present specification does not intend to distinguish between elements that have the same function but have different names. In the following description and claims, words such as “comprising”, “including”, “containing”, and “having” are open-ended words, so they should be interpreted as meaning “containing but not limited to . . . ”. Therefore, when the terms “comprising”, “including”, “containing” and/or “having” are used in the description of the present disclosure, they specify the existence of corresponding features, regions, steps, operations and/or components, but do not exclude the existence of one or more corresponding features, regions, steps, operations and/or components.

The terms, such as “about”, “substantially”, or “approximately”, are generally interpreted as within 10%, 5%, 3%, 2%, 1%, or 0.5% of a given value or range. The quantity given here is an approximate quantity, that is, without specifying “about”, “approximately”, “substantially” and “approximately”, “about”, “approximately”, “substantially” and “approximately” can still be implied. Furthermore, when a value is “in a range from a first value to a second value” or “in a range between a first value and a second value”, the value can be the first value, the second value, or another value between the first value and the second value.

In the present specification, except otherwise specified, the terms (including technical and scientific terms) used herein have the meanings generally known by a person skilled in the art. It should be noted that, except otherwise specified, in the embodiments of the present disclosure, these terms (for example, the terms defined in the generally used dictionary) should have the meanings identical to those known in the art, the background of the present disclosure or the context of the present specification, and should not be read by an ideal or over-formal way.

In addition, relative terms such as “below” or “under” and “on”, “above” or “over” may be used in the embodiments to describe the relative relationship between one element and another element in the drawings. It will be understood that if the device in the drawing was turned upside down, elements described on the “lower” side would then become elements described on the “upper” side. When a unit (for example, a layer or a region) is referred to as being “on” another unit, it can be directly on the another unit or there may be other units therebetween. Furthermore, when a unit is said to be “directly on another unit”, there is no unit therebetween. Moreover, when a unit is said to be “on another unit”, the two have a top-down relationship in a top view, and the unit can be disposed above or below the another unit, and the top-bottom relationship depends on the orientation of the device.

It the present disclosure, the distance, the width, the length and the thickness may be measured by using an optical microscope (OM) or by using a cross-sectional image of a scanning electron microscope (SEM), but the present disclosure is not limited thereto. In addition, any two values or directions used for comparison may have a certain error. If the first value is equal to the second value, it implies that there may be an error of about 10% between the first value and the second value. If the first direction is perpendicular to the second direction, the angle between the first direction and the second direction may be between 80° and 100°. If the first direction is parallel to the second direction, the angle between the first direction and the second direction may be between 0° and 10°.

It should be noted that the technical solutions provided in the following different embodiments can be replaced, combined or mixed with each other to form another embodiment without violating the spirit of the present disclosure.

The electronic device of the present disclosure may include, for example, a display device, a sensing device, an antenna device, a touch device, a tiled device, or other suitable electronic devices, but the present disclosure is not limited thereto. The display device of the present disclosure may be a non-self-luminous display device or a self-luminous display device, such as a liquid crystal display, a cholesteric liquid crystal display, an electro-phoretic display, an organic light emitting diode display or a light emitting diode display, but the present disclosure is not limited thereto. The display device may include a light emitting diode, a light conversion layer or other suitable materials, or a combination thereof, but the present disclosure is not limited thereto. The light emitting diode may include, for example, an organic light emitting diode (OLED), a mini LED, a micro LED or a quantum dot LED (which may include QLED or QDLED), but the present disclosure is not limited thereto. The light conversion layer may include wavelength conversion materials and/or light filtering materials, and the light conversion layer may comprise, for example, fluorescence, phosphors, quantum dots (QDs), other suitable materials or a combination thereof, but the present disclosure is not limited thereto. The sensing device may, for example, include a biosensor, a touch sensor, a fingerprint sensor, an infrared sensor, a temperature sensor, other suitable sensors, or a combination of the above types of sensors. The antenna device may be, for example, a liquid crystal antenna or other types of antennas, but the present disclosure is not limited thereto. The tiled device may be, for example, a tiled display device or a tiled antenna device, but the present disclosure is not limited thereto. The electronic device may comprise an electronic component, which may include passive components, active components, or a combination thereof, such as capacitors, resistors, inductors, varactor diodes, variable capacitors, filters, diodes, transistors, sensors, micro-electromechanical systems (MEMS), chips, etc., but the present disclosure is not limited thereto. It should be noted that the electronic device of the preset disclosure may be any combination of the above devices, but the present disclosure is not limited thereto.

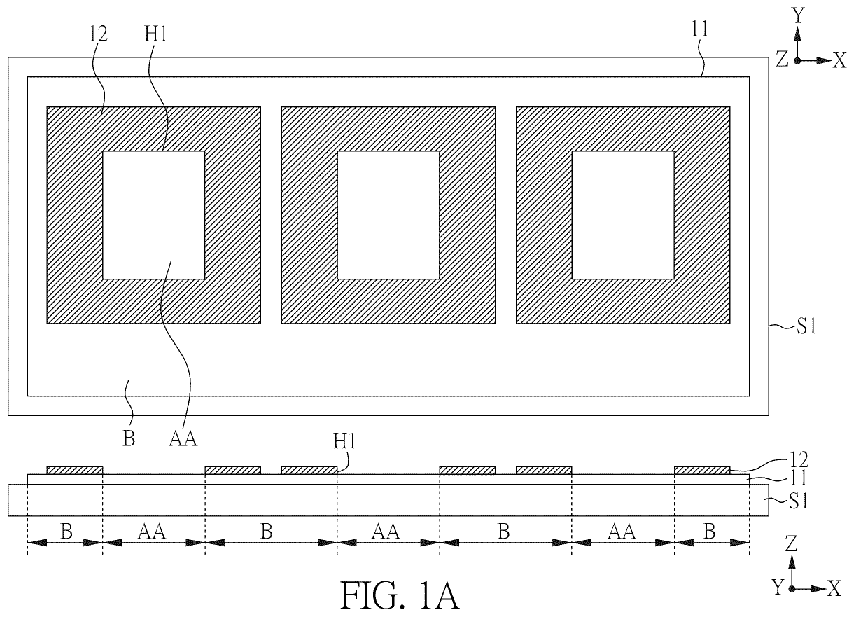

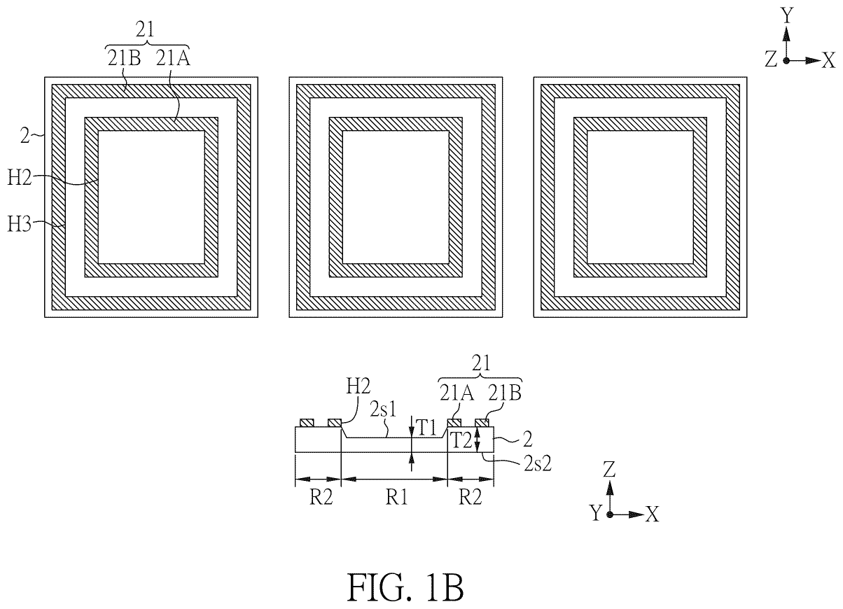

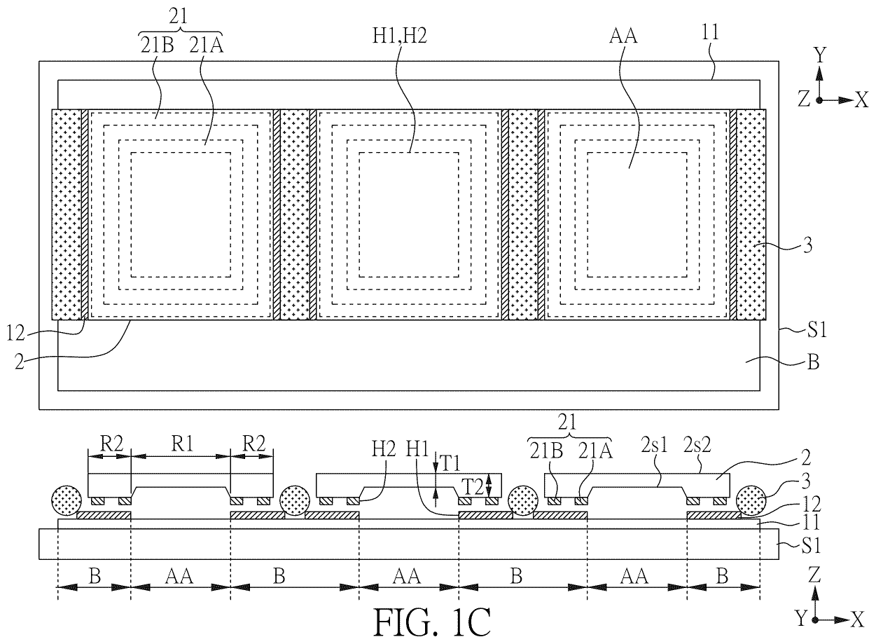

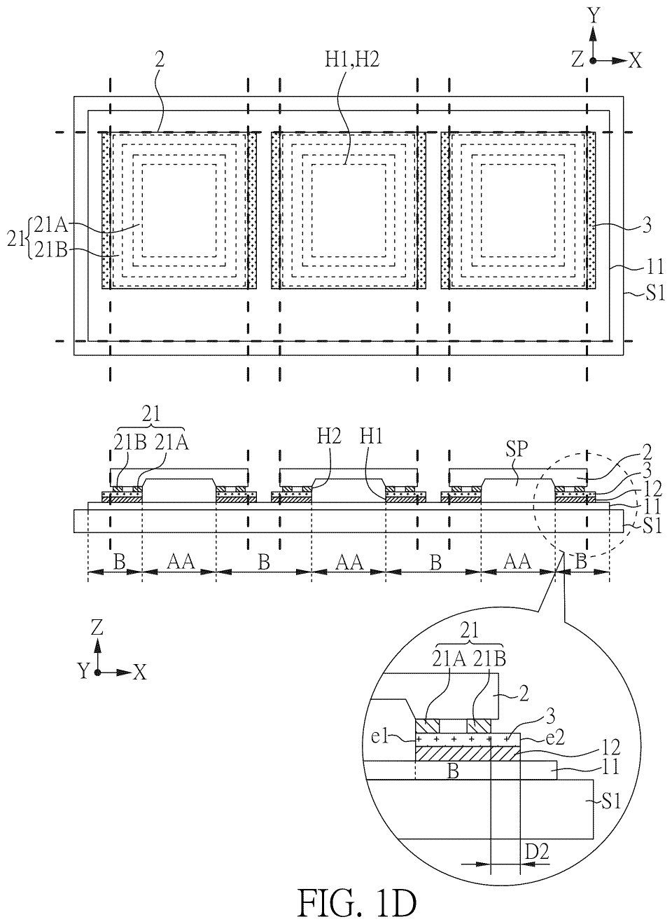

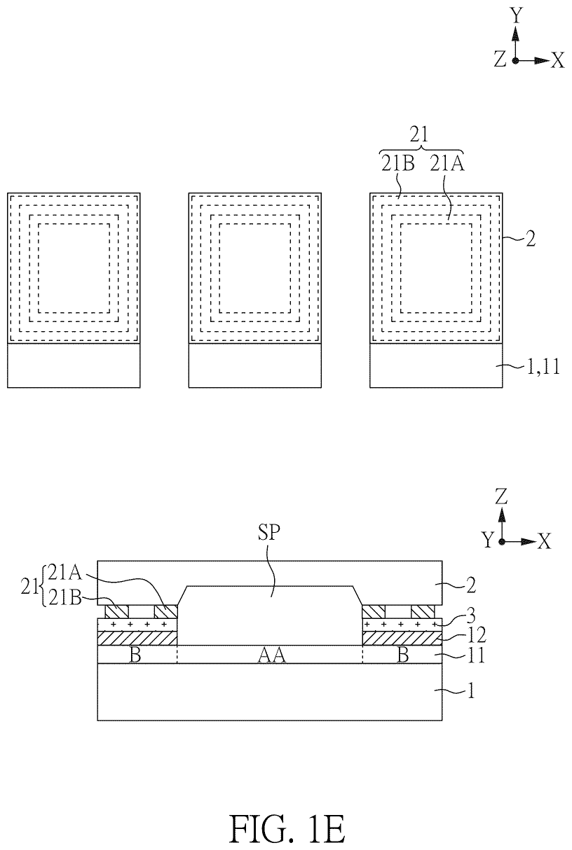

FIG. 1A to FIG. 1E are schematic views showing a method for manufacturing an electronic device according to one embodiment of the present disclosure. The upper views of FIG. 1A to FIG. 1E are top schematic views and the lower views thereof are cross-sectional schematic views. For the convenience of explanation, some components are omitted in the schematic views.

In one embodiment of the present disclosure, as shown in FIG. 1A, a method for manufacturing an electronic device may comprise: providing a mother substrate S1; forming an element layer 11 on the mother substrate S1, wherein the element layer 11 comprises a plurality of active areas AA and a peripheral area B surrounding the active area AAs; and forming a plurality of first bonding pads 12 on the peripheral area B of the element layer 11.

More specifically, as shown in FIG. 1A, the first bonding pads 12 may respectively comprise an opening H1. In a top view direction Z, a projection area of the opening H1 of the first bonding pad 12 on the mother substrate S1 may be approximately equal to a projection area of the active area AA of the element layer 11 on the mother substrate S1, and the openings H1 may respectively expose the active areas AA of the element layer 11. In the top view direction Z, the first bonding pad 12 may be disposed surrounding the active area AA of the element layer 11.

In the present disclosure, the material of the mother substrate S1 may comprise glass, quartz, sapphire, ceramics, polycarbonate (PC), polyimide (PI), polypropylene (PP), polyethylene terephthalate (PET), polymethylmethacrylate (PMMA), other suitable materials or a combination thereof, but the present disclosure is not limited thereto.

In the present disclosure, the active area AA of the element layer 11 may comprise a circuit, a conductive line, a conductive pad, a sensing unit, a driving circuit, other suitable elements or a combination thereof. Suitable elements may include passive components, active components or a combination thereof, such as capacitors, resistors, inductors, diodes, transistors, etc., but the present disclosure is not limited thereto. The diode may include a light emitting diode or a photodiode. The light emitting diode may comprise an organic light emitting diode (OLED), a mini LED, a micro LED or a quantum dot (QD) LED (which may be, for example, a QLED or a QDLED) or other suitable materials or a combination thereof, but the present disclosure is not limited thereto. In one embodiment of the present disclosure, the element layer 11 may be formed, for example, by thin films, which may comprise a plurality of insulating layers and a plurality of metal layers, but the present disclosure is not limited thereto. In the present disclosure, the peripheral area B of the element layer 11 may comprise a metal layer, a conductive pad and an insulating layer, but the present disclosure is not limited thereto. In one embodiment of the present disclosure, the active area AA of the element layer 11 may comprise a plurality of sensing units, and the sensing units may be, for example, a wavelength sensor or a temperature sensor, but the present disclosure is not limited thereto. In the present disclosure, the size of the active area AA of the element layer 11 is not particularly limited, and the size of each active area AA may be adjusted according to the needs, but the present disclosure is not limited thereto. The “size of the active area” refers to, for example, the maximum width or length of the active area AA in one direction (for example, the X direction).

In the present disclosure, the material of the first bonding pad 12 may comprise tin (Sn), aluminum (Al), nickel (Ni), gold (Au), palladium (Pd), copper (Cu), titanium (Ti), an alloy thereof, or a combination thereof. In the present disclosure, the first bonding pad 12 may have a single layer or multi-layer structure, and each layer may be formed by the same or different materials. For example, the first bonding pad 12 may have a multi-layer structure of Cu/Au, Ti/Au, Mo/Cu/Sn, Ti/Cu/Au, Al/Ni/Au, Al/Ni/Cu, Al/Ni/Pd/Au, Cu/Ni/Au, Cu/Au/Pd/Au, Cu/Sn or Ti/Cu, but the present disclosure is not limited thereto. In the present disclosure, the thickness of the first bonding pad 12 may be 0.1 μm to 35 μm, for example, 0.4 μm to 35 μm or 0.5 μm to 5 μm, but the present disclosure is not limited thereto. When the first bonding pad 12 comprise a gold (Au) layer, the thickness of the gold (Au) layer may be 0.1 μm to 10 μm, 0.4 μm to 10 μm, 0.4 μm to 5 μm, 0.5 μm to 2 μm or 0.4 μm to 0.8 μm, but the present disclosure is not limited thereto. The gold layer may be used to provide good adhesion. When the first bonding pad 12 comprise a palladium (Pd) layer, the thickness of the palladium (Pd) may be 0.1 μm to 10 μm, 0.1 μm to 5 μm, 0.2 μm to 5 μm or 0.1 μm to 0.5 μm, but the present disclosure is not limited thereto. The palladium layer may be used to prevent the diffusion of metal materials in the upper and lower layers, which may cause abnormalities in subsequent steps. In addition, when the first bonding pad 12 has a palladium layer and the palladium layer has the aforesaid thickness, a good adhesion effect can be provided. For example, when the palladium layer has the aforesaid thickness, the probability of the gas in the environment passing through the palladium layer and reacting with other metal layers in the first bonding pad 12 can be reduced, thereby reducing the possibility of deterioration of other metal layers in the first bonding pad 12. When the first bonding pad 12 comprises an aluminum (Al) layer, the thickness of the aluminum (Al) may be 0.4 μm to 1 μm, 0.5 μm to 0.8 μm or 0.4 μm to 0.8 μm, but the present disclosure is not limited thereto. The aluminum (Al) layer may be formed on the mother substrate S1 as a base layer of the first bonding pad 12. When the aluminum (Al) layer has the aforesaid thickness, a better reliability of the first bonding pad 12 can be provided. When the first bonding pad 12 comprises a nickel (Ni) layer, the thickness of the nickel (Ni) layer may be 1.2 μm to 10 μm, 1.2 μm to 5 μm or 1.5 μm to 5 μm, but the present disclosure is not limited thereto. The nickel (Ni) layer may be formed on the aluminum (Al) layer to facilitate the formation of other metal layers of the first bonding pad 12. In the present disclosure, the “thickness of the first bonding pad 12” may be referred to, for example, a distance between one side of the first bonding pad 12 away from the mother substrate S1 and one side of the first bonding pad 12 close to the mother substrate S1 in a normal direction Z. The “thickness of each metal layer of the first bonding pad 12” refers to the distance between one side of one metal layer away from the mother substrate S1 and one side of the one metal layer close to the mother substrate S1 in the normal direction Z. In the present disclosure, any suitable method may be used to form the first bonding pad 12, and suitable methods may include electroplating, chemical plating, chemical vapor deposition, physical vapor deposition, atomic layer deposition (ALD), sputtering, lamination, coating or a combination thereof, but the present disclosure is not limited thereto. The “coating” may be, for example, dip coating, spin coating, roller coating, blade coating, spray coating or a combination thereof, but the present disclosure is not limited thereto.

Next, as shown in FIG. 1B, a plurality of second substrates 2 are provided; and a plurality of second bonding pads 21 are formed on the second substrates 2, wherein each second bonding pad 21 respectively comprises a first part 21A and a second part 21B surrounding the first part 21A.

More specifically, as shown in FIG. 1B, the second substrate 2 comprises a first region R1 and a second region R2 surrounding the first region R1, and the thickness T1 of at least part of the first region R1 of the second substrate 2 is less than the thickness T2 of the second region R2 of the second substrate 2. The “thickness” refers to, for example, the distance between the side 2s1 of the second substrate 2 close to the first substrate 1 (as shown in FIG. 1E) and another side 2s2 of the second substrate 2 away from the first substrate 1 (as shown in FIG. 1E) in a normal direction Z of the second substrate 2. The first part 21A and the second part 21B of the second bonding pad 21 are respectively disposed in the second region R2 of the second substrate 2. In the top view direction Z, the first part 21A and the second part 21B of the second bonding pad 21 respectively form a close surrounding structure, wherein the first part 21A of the second bonding pad 21 comprises an opening H2, and the second part 21B of the second bonding pad 21 comprises an opening H3. In the top view direction Z, a projection area of the opening H2 on the second substrate 2 may be approximately equal to a projection area of the first region R1 of the second substrate 2 on the second substrate 2, and a projection area of the opening H3 on the second substrate 2 is greater than a projection area of the first region R1 of the second substrate 2 on the second substrate 2.

In the present disclosure, the material of the second substrate 2 may comprise silicon, germanium (Ge), zinc sulfide (ZnS), zinc selenide (ZnSe), gallium arsenide (GaAs), chalcogenide or a combination thereof, but the present disclosure is not limited thereto. In one embodiment of the present disclosure, the second substrate 2 may be composed of, for example, a silicon substrate that allows light with specific wavelengths (for example, light with wavelengths of 5 μm to 15 μm) to pass through, but the present disclosure is not limited thereto. In the present disclosure, the second bonding pad 21 may be prepared by the same or different materials of the first bonding pad 12, and the material of the second bonding pad 21 can be referred to that of the first bonding pad 12. In addition, when the second bonding pad comprises a single layer or multi-layer structure, the materials and related thickness of each layer can be referred to those of the first bonding pad 12, and are not described again here. In the present disclosure, the thickness of the second bonding pad 21 may be 0.1 μm to 35 μm, for example, 0.4 μm to 35 μm or 0.5 μm to 5 μm, but the present disclosure is not limited thereto. In one embodiment of the present disclosure, the thickness of the second bonding pad 21 may be greater than or equal to the thickness of the first bonding pad 12, but the present disclosure is not limited thereto. In the present disclosure, the “thickness of the second bonding pad 21” refers to, for example, the distance between one side of the second bonding pad 21 away from the second substrate 2 and one side of the second bonding pad 21 close to the second substrate 2 in the normal direction Z. When the second bonding pad comprises a multi-layer structure, the “thickness of each metal layer of the second bonding pad 21” refers to the distance between one side of one metal layer away from the second substrate 2 and one side of the one metal layer close to the second substrate 2 in the normal direction Z. In the present disclosure, any suitable method may be used to prepare the second bonding pad 21, and suitable method may be referred to the method for forming the first bonding pad 12 and is not described again here.

Then, as shown in FIG. 1C, the second substrate 2 is disposed on the element layer 11 to make the second bonding pad 21 and the first bonding pad 12 overlapped, and a bonding material 3 is applied on two adjacent first bonding pads 12. In one embodiment of the present disclosure, the second substrate 2 may be firstly disposed on the element layer 11, and then the bonding material 3 is applied on two adjacent first bonding pads 12, but the present disclosure is not limited thereto. In other embodiments, the bonding material 3 may be applied on two adjacent first bonding pads 12 first, and then the second substrate 2 is disposed on the element layer 11. In addition, as shown in FIG. 1C, the second substrate 2 is placed on the element layer 11 with the second bonding pad 21 facing the first bonding pad 12. Thus, the second bonding pad 21 is closer to the first bonding pad 12 than the second substrate 2.

In one embodiment of the present disclosure, as shown in FIG. 1C, the bonding material 3 may directly contact the first bonding pad 12, but the present disclosure is not limited thereto. In one embodiment of the present disclosure, as shown in FIG. 1C, when the second substrate 2 is placed on the element layer 11, in the top view direction Z, the first region R1 of the second substrate 2 and the active area AA of the element layer 11 may be approximately overlapped, and the second region R2 of the second substrate 2 and a part of the peripheral area B of the element layer 11 may be overlapped. In one embodiment of the present disclosure, as shown in FIG. 1C, when the second substrate 2 is place on the element layer 11, in the top view direction Z, the opening H2 of the first part 21A of the second bonding pad 21 and the active area AA of the element layer 11 may be approximately overlapped. In one embodiment of the present disclosure, as shown in FIG. 1C, when the second substrate 2 is placed on the element layer 11, in the top view direction Z, the opening H2 of the first part 21A of the second bonding pad 21 and the opening H1 of the first bonding pad 12 may be approximately overlapped.

In the present disclosure, the bonding material 3 may comprise solder, solder paste or a combination thereof, but the present disclosure is not limited thereto. In the present disclosure, the bonding material 3 may comprise tin, tin alloy or a combination thereof, but the present disclosure is not limited thereto. Since tin has a low melting point, when the bonding material contains tin, the temperature of the subsequent melting bonding material can be lowered, thereby reducing damage to the substrate due to excessive temperature.

Then, as shown in FIG. 1D, the bonding material 3 is heated, so the bonding material 3 melts and diffuses between the first part 21A of the second bonding pad 21 and the first bonding pad 12 and between the second part 21B of the second bonding pad 21 and the first bonding pad 12. More specifically, as shown in FIG. 1D, by heating the bonding material 3, the bonding material 3 melts into liquid or semi-liquid state and flows between the first bonding pad 12 and the second bonding pad 21, so the first bonding pad 12 and the second bonding pad 21 are bonded through the bonding material 3, thereby achieving the purpose of assembling the mother substrate S1 and the second substrate 2. Thus, a sealed space SP may be formed between the mother substrate S1 and the second substrate 2. Since the first part 21A and the second part 21B of the second bonding pad 21 respectively has a close surrounding structure, the vacuum effect in the sealed space SP can be enhanced, thereby improving the reliability of the electronic device and reducing the interference of external airflow on the electronic device. In one embodiment of the present disclosure, when assembling the substrates, if there is a defect in the first part 21A or the second part 21B of the second bonding pad 21, bonding can be performed through another part, thereby improving the packaging error tolerance rate and facilitating process application. In one embodiment of the present disclosure, the sealed space SP may be in a vacuum or near-vacuum state to reduce the interference of other external environments (such as moisture, air, etc.) on the components in the active area AA.

In one embodiment of the present disclosure, the temperature for heating the bonding material 3 may be greater than or equal to the melting temperature of the bonding material 3, for example, may be 90° C. to 450° C., 150° C. to 450° C. or 200° C. to 400° C., but the present disclosure is not limited thereto. In one embodiment of the present disclosure, other process conditions can be added according to process requirements, such as pressurization, to assist the effect of the assembly. The “pressurization” refers to a situation where a stress, for example, greater than 0.1 MPa, is applied during the process of melting the bonding material 3.

In the present disclosure, since the first bonding pad 12 and/or the second bonding pad 21 has affinity with the bonding material 3, the bonding material 3 flows along the position of the first bonding pad 12 and/or the second bonding pad 21 when the bonding material 3 is heated. Thus, when the electronic device is manufactured, the possibility of the bonding material 3 overflowing into the sealed space SP can be reduced, thereby reducing the impact or interference of the overflowed bonding material 3 on the function of the active area AA. As shown in FIG. 1D, in the top view direction Z, the bonding material 3 and at least part of the first bonding pad 12 are overlapped. In one embodiment of the present disclosure, the projection area of the bonding material 3 on the mother substrate S1 may be approximately equal to the projection area of the first bonding pad 12 on the mother substrate S1. Thus, in the top view direction Z, the first bonding pad 12 is covered by the bonding material 3. In the present disclosure, as shown in FIG. 1D, the bonding material 3 has a first edge eland a second edge e2, the first edge e1 is adjacent to the active area AA, and the second edge e2 is opposite to the first edge e1. In a direction (for example, the X direction), the distance D1 between the first edge e1 and the first part 21A of the second bonding pad 21 is less than the distance D2 between the second edge e2 and the second part 21B of the second bonding pad 21. In one embodiment of the present disclosure, as shown in FIG. 1D, the distance D1 between the first edge e1 of the bonding material 3 and the first part 21A of the second bonding pad 21 may be, for example, 0. Thus, the distance D1 is not shown in FIG. 1D, but the present disclosure is not limited thereto. In other embodiments, the distance D1 may be greater than 0 and less than the distance D2. The “distance D1” refers to, for example, the distance between the first edge e1 of the bonding material 3 and the position where the upper surface of the bonding material 3 contacts the first part 21A of the second bonding pad 21, which is measured along the upper surface of the bonding material 3 in a cross section. The “distance D2” refers to, for example, the distance between the second edge e2 of the bonding material 3 and the position where the upper surface of the bonding material 3 contacts the second part 21B of the second bonding pad 21, which is measured along the upper surface of the bonding material 3 in a cross section.

In one embodiment of the present disclosure, before the step of heating the bonding material 3, the method may further comprise: placing the mother substrate S1 in a chamber (not shown in the figure) and vacuuming the chamber. In the present disclosure, the above-mentioned vacuuming step can be performed at any stage before heating the bonding material 3. For example, after providing the mother substrate S1, the mother substrate S1 is placed in the chamber and the chamber is vacuumed, and then the subsequent steps are performed; or after placing the second substrate 2 on the element layer 11, the above-mentioned element may be placed in a chamber and the chamber is vacuumed, and then subsequent steps such as applying bonding material 3 on two adjacent first bonding pads 12 may be performed. However, the present disclosure is not limited thereto. In the present disclosure, the “vacuum” refers to the pressure inside the chamber is, for example, less than or equal to 1 torr, for example, the pressure inside the chamber may be 10-3 torr to 1 torr or 10-7 torr to 1 torr, but the present disclosure is not limited thereto. In the present disclosure, since the plurality of second substrates 2 are assembled with one mother substrate S1, it is unlikely that the vacuum degree at the center and the edge of the mother substrate S1 will be inconsistent during the vacuuming step, thereby improving the vacuum effect in the sealed space SP.

Next, as shown in FIG. 1D and FIG. 1E, the mother substrate S1 and the element layer 11 are cut to form a plurality of electronic devices. More specifically, for example, the bonding material 3, the first bonding pad 12, the element layer 11 and the mother substrate S1 can be cut along the dash lines in FIG. 1D to form a plurality of electronic devices of appropriate sizes, as shown in FIG. 1E. The first substrate 1 shown in FIG. 1E is formed by cutting the mother substrate S1. In the present embodiment, the cut is performed according to the dash line in FIG. 1D approximately along the edge of the element layer 11 and the size of the second substrate 2. Thus, as shown in FIG. 1E, the projection area of the cut element layer 11 in the electronic device can be approximately equal to the projection area of the first substrate 1. However, in other embodiments of the present disclosure, the projection area of the first substrate 1 in the electronic device may be greater than the projection area of the cut element layer 11. In one embodiment of the present disclosure, in the top view direction Z, the area of the cut first substrate 1 of the electronic device (as shown in FIG. 1E) is greater than the area of the second substrate 2, and the orthographic projection of the second substrate 2 completely falls in to the first substrate 1. That is, the second substrate 2 may not be cut during the cutting step, so as to reduce the risk of the second substrate 2 being broken or the second part 21B of the second bonding pad 21 being damaged, thereby improving the product yield. In the present disclosure, the mother substrate S1 and the element layer 11 may be cut by laser cutting, wheel cutting or a combination thereof. In one embodiment of the present disclosure, the electronic device may have the ability to receive or send signals, such as sensing temperature or emitting light, but the present disclosure is not limited thereto.

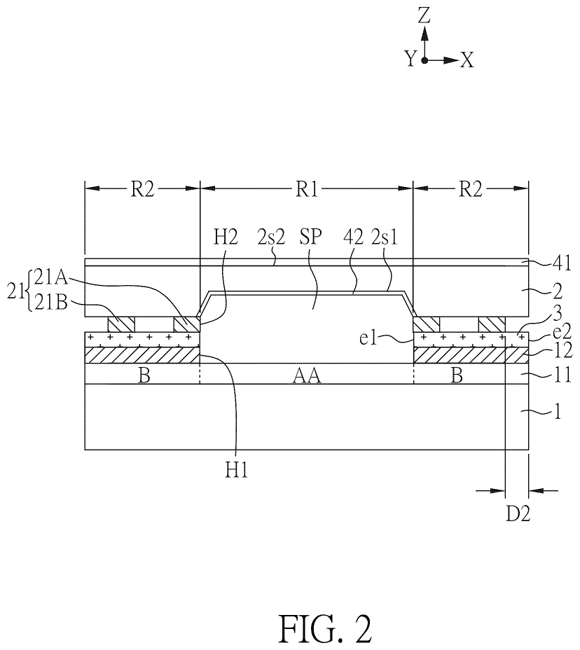

FIG. 2 is a cross-sectional schematic view showing an electronic device according to one embodiment of the present disclosure.

In one embodiment of the present disclosure, through the manufacturing method of FIG. 1A to FIG. 1E described above, the electronic device, for example, shown in FIG. 2 can be obtained. In the present disclosure, as shown in FIG. 2, the electronic device may comprise: a first substrate 1; an element layer 11 disposed on the first substrate 1 and comprising an active area AA and a peripheral area B surrounding the active area AA; a first bonding pad 12 disposed on the peripheral area B of the element layer 11; a second substrate 2 disposed opposite to the first substrate 1; a second bonding pad 21 disposed on the second substrate 2 and comprising a first part 21A and a second part 21B surrounding the first part 21A; and a bonding material 3 disposed between the first part 21A of the second bonding pad 21 and the first bonding pad 12 and between the second part 21B of the second bonding pad 21 and the first bonding pad 12.

In the present disclosure, as shown in FIG. 2, the bonding material 3 has a first edge e1 and a second edge e2, the first edge e1 is adjacent to the active area AA, and the second edge e2 is opposite to the first edge e1. In one direction (for example, the X direction), the distance D1 between the first edge e1 and the first part 21A of the second bonding pad 21 is less than the distance D2 between the second edge e2 and the second part 21B of the second bonding pad 21. In one embodiment of the present disclosure, as shown in FIG. 2, the distance D1 between the first edge e1 and the first part 21A may be, for example, 0. Thus, the distance D1 is not shown in FIG. 2, but the present disclosure is not limited thereto.

In the present disclosure, as shown in FIG. 2, the first bonding pad 12 may comprise an opening H1. In the top view direction Z, the projection area of the opening H1 of the first bonding pad 12 on the first substrate 1 may be approximately equal to the projection area of the active area AA of the element layer 11 on the first substrate 1, and the opening H1 may expose the active area AA of the element layer 11. The first part 21A of the second bonding pad 21 may comprise an opening H2. In the top view direction Z, the projection area of the opening H2 on the first substrate 1 may be approximately equal to the projection area of the first region R1 of the second substrate 2 on the first substrate 1. In one embodiment of the present disclosure, as shown in FIG. 2, the projection area of the opening H1 of the first bonding pad 12 on the first substrate 1 may be approximately equal to the projection area of the opening H2 of the first part 21A of the second bonding pad 21 on the first substrate 1.

In the present disclosure, the material of the first substrate 1 may be the same as that of the mother substrate S1, and the materials and other features of the element layer 11, the first bonding pad 12, the second substrate 2, the second bonding pad 21 and the bonding material 3 can be as those described above, and are not described again here. In one embodiment of the present disclosure, the active area AA of the element layer 11 may comprise a plurality of sensing units. Thus, the electronic device of the present disclosure may be, for example, a sensing device, but the present disclosure is not limited thereto. In one embodiment of the present disclosure, the electronic device may have a function of emitting light with specific wavelengths (for example, the light with wavelengths of 5 μm to 15 μm, 100 nm to 400 nm, 380 nm to 750 nm, or 780 nm to 950 nm) or sensing light with specific wavelengths (for example, the light with wavelengths of 5 μm to 15 μm), but the present disclosure is not limited thereto.

In one embodiment of the present disclosure, as shown in FIG. 2, the electronic device may further comprise an anti-reflective layer 41 disposed on the second substrate 2. More specifically, the second bonding pad 21 is disposed on a side 2s1 of the second substrate 2 facing the first substrate 1, and the anti-reflective layer 41 is disposed on a side 2s2 of the second substrate 2 away from the first substrate 1. In other words, the second substrate 2 is disposed between the second bonding pad 21 and the anti-reflective layer 41. In one embodiment of the present disclosure, as shown in FIG. 2, the electronic device may further comprise another anti-reflective layer 42 disposed on a side 2s1 of the second substrate 2 close to the first substrate 1. More specifically, another anti-reflective layer 42 may be disposed on the first region R1 of the second substrate 2. Thus, in the top view direction Z, the anti-reflective layer 42 and the first region R1 of the second substrate 2 may be overlapped, and the anti-reflective layer 42 and the second region R2 of the second substrate 2 may not be overlapped, but the present disclosure is not limited thereto. The anti-reflective layer 41 and the anti-reflective layer 42 can be used to reduce the reflection of light within a specified wavelength range and/or block the light outside the specified wavelength range from entering, so as to improve the transmittance of light within the specified wavelength range. In one embodiment of the present disclosure, the light within the specified wavelength may be, for example, the light with wavelengths of 5 μm to 15 μm, but the present disclosure is not limited thereto.

In the present disclosure, the same or different materials may be used to prepare the anti-reflective layer 41 and the anti-reflective layer 42. Suitable materials may respectively comprise silicon, germanium (Ge), zinc sulfide (ZnS), zinc selenide (ZnSe), magnesium fluoride (MgF₂), beryllium fluoride (BeF₂), potassium chloride, arsenic trisulfide (As₂S₃), silicon oxide, silicon nitride, silicon oxynitride, indium tin oxide (ITO), aluminum zinc oxide (AZO), indium gallium zinc oxide (IGZO), antimony tin oxide (ATO), fluorine-doped tin oxide (FTO) or a combination thereof, but the present disclosure is not limited thereto. In the present disclosure, the anti-reflective layer 41 and the anti-reflective layer 42 may selectively comprise a plurality of high refractive index layers and a plurality of low refractive index layers, wherein the high refractive index layers and the low refractive index layers are alternately laminated. By designing a laminated structure of layers with different refractive indices, the anti-reflective layer 41 and/or the anti-reflective layer 42 can achieve the effect of reducing reflected light. The “high refractive index layer” refers to, for example, the film with the refractive index greater than or equal to 1.38 and less than or equal to 1.48. The “low refractive index layer” refers to, for example, the film with refractive index greater than or equal to 1.8 and less than or equal to 2.1.

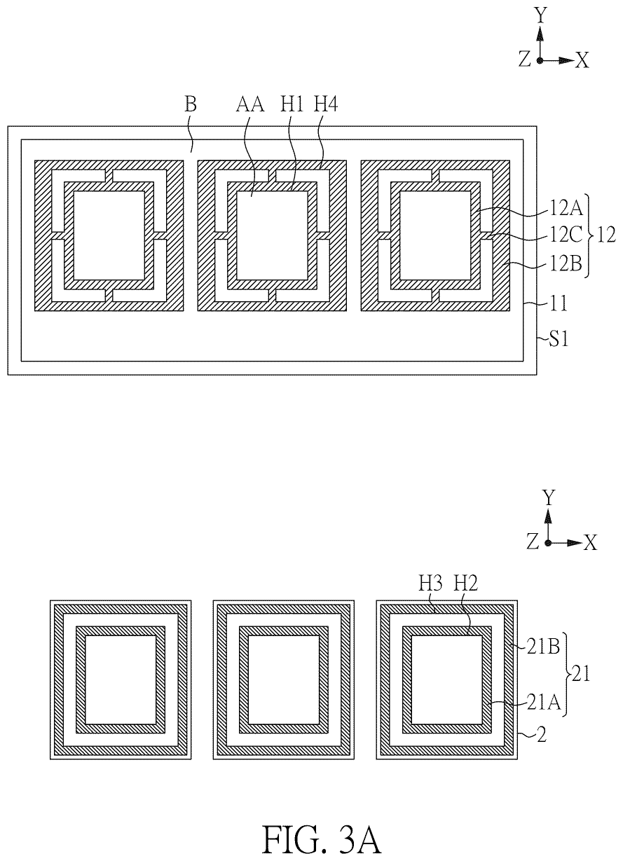

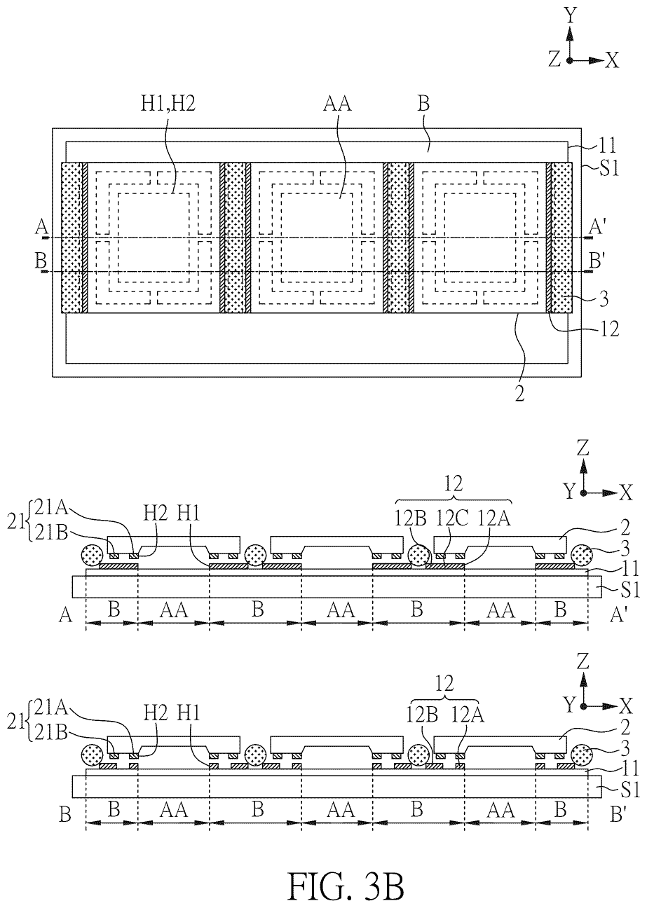

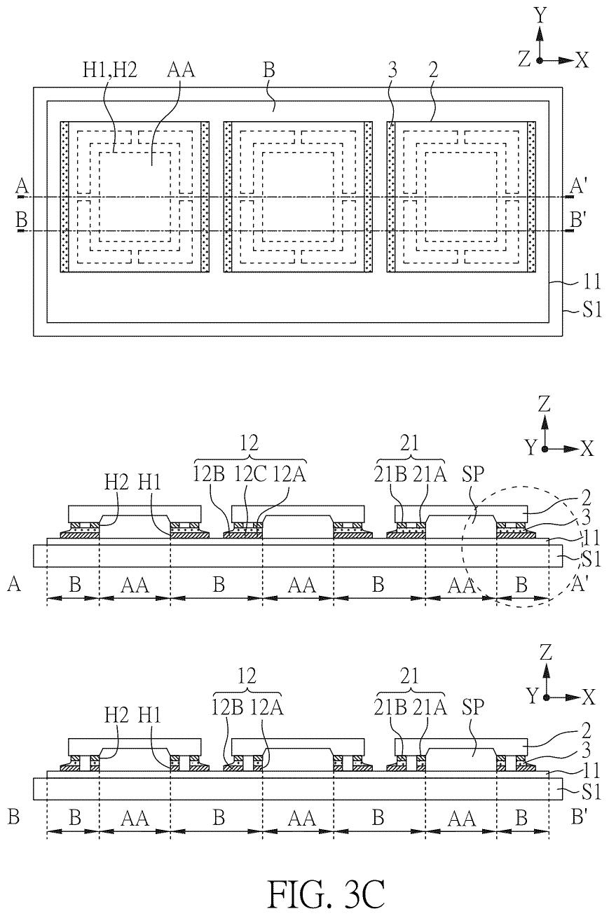

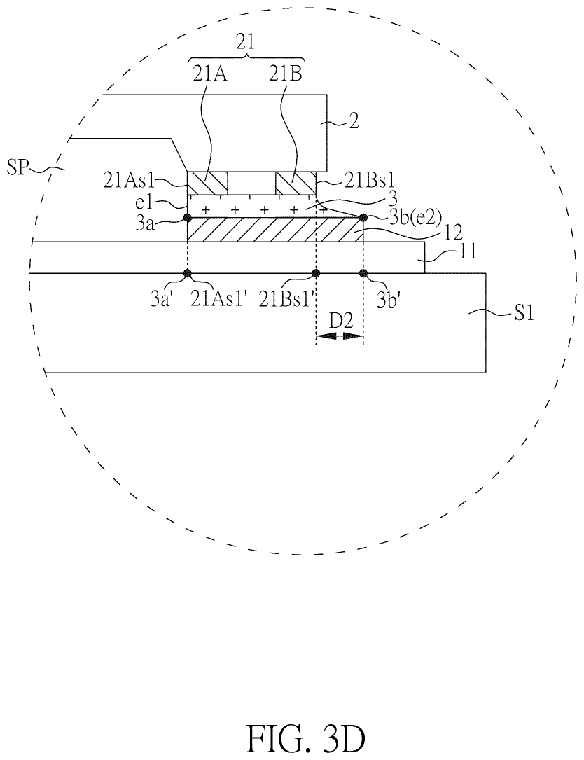

FIG. 3A to FIG. 3C are schematic views showing a method for manufacturing an electronic device according to one embodiment of the present disclosure. FIG. 3D is a partial enlarged view of FIG. 3C. The upper view of FIG. 3A is a top schematic view of the mother substrate, and the lower view thereof is a top schematic view of the second substrate. The upper views of FIG. 3B and FIG. 3C are top schematic views, and the lower views thereof are cross-sectional schematic views. In addition, the manufacturing method shown in FIG. 3A to FIG. 3C is similar to that shown in FIG. 1A to FIG. 1E, except for the following differences.

In one embodiment of the present disclosure, as shown in FIG. 3A, the method for manufacturing the electronic device may comprise: providing a mother substrate S1; forming an element layer 11 on the mother substrate S1; forming a plurality of first bonding pads 12 on the peripheral area B of the element layer 11; providing a plurality of second substrates 2; and forming a plurality of second bonding pads 21 on the second substrate 2. The first bonding pad 12 comprises a third part 12A, a fourth part 12B and a first connection portion 12C, the fourth part 12B surrounds the third part 12A, and the first connection portion 12C connects to the third part 12A and the fourth part 12B respectively. The second bonding pad 21 comprises a first part 21A and a second part 21B, and the second part 21B surrounds the first part 21A.

More specifically, as shown in FIG. 3A, in the top view direction Z, the third part 12A and the fourth part 12B of the first bonding pad 12 respectively form a close surrounding structure, and the two close surrounding structures are connected to each other through a first connection portion 12C. The third part 12A of the first bonding pad 12 comprises an opening H1, the fourth part 12B of the first bonding pad 12 comprises an opening H4, and the opening H1 exposes the active area AA of the element layer 11. In the top view direction Z, the projection area of the opening H1 on the mother substrate S1 may be approximately equal to the projection area of the active area AA on the mother substrate S1. In addition, in the present embodiment, the third part 12A of the first bonding pad 12 can be connected to the fourth part 12B through four first connection portions 12C, but the present disclosure is not limited thereto. In other embodiments, the number of the first connection portions 12C can be adjusted according to the needs.

In one embodiment of the present disclosure, as shown in FIG. 3A, the opening H1 of the third part 12A of the first bonding pad 12 may be approximately equal to the opening H2 of the first part 21A of the second bonding pad 21, and the opening H4 of the fourth part 12B of the first bonding pad 12 may be approximately equal to the opening H3 of the second part 21B of the second bonding pad 21. Thus, in the subsequent assembling step, in the top view direction Z, the third part 12A of the first bonding pad 12 and the first part 21A of the second bonding pad 21 are approximately overlapped, and the fourth part 12B of the first bonding pad 12 and the second part 21B of the second bonding pad 21 are approximately overlapped.

Next, as shown in FIG. 3B, the second substrate 2 is placed on the element layer 11, so that the second bonding pad 21 and the first bonding pad 12 are overlapped. Then, a bonding material 3 is applied on two adjacent first bonding pads 12. More specifically, as shown in FIG. 3A and FIG. 3B, the second substrate 2 is disposed on the element layer 11. In the top view direction Z, the first part 21A of the second bonding pad 21 and the third part 12A of the first bonding pad 12 are approximately overlapped, and the second part 21B of the second bonding pad 21 and the fourth part 12B of the first bonding pad 12 are approximately overlapped. In one embodiment of the present disclosure, the order of steps of placing the second substrate 2 on the element layer 11 and applying the bonding material 3 on two adjacent first bonding pads 12 is not particularly limited, may be adjusted according to the needs, and is not described again here.

In one embodiment of the present disclosure, FIG. 3B shows a cross-sectional views of the line A-A′ passing through the first connection portion 12C of the first bonding pad 12 and the line B-B′ not passing through the first connection portion 12C of the first bonding pad 12, wherein the bonding material 3 may directly contact the fourth part 12B of the first bonding pad 12, but the present disclosure is not limited thereto. In other embodiments, the bonding material 3 may directly contact the fourth part 12B of the first bonding pad 12 and the element layer 11.

Then, as shown in FIG. 3C, the bonding material 3 is heated, and the bonding material 3 melts and diffuses between the first part 21A of the second bonding pad 21 and the third part 12A of the first bonding pad 12, and between the second part 21B of the second bonding pad 21 and the fourth part 12B of the first bonding pad 12. More specifically, since the first bonding pad 12 and/or the second bonding pad 21 have affinity with the bonding material 3, the bonding material 3 is heated to melt into a liquid or semi-liquid state and flow between the fourth part 12B of the first bonding pad 12 and the second part 21B of the second bonding pad 21. Then, the bonding material 3 may pass the first connection portion 12C of the first bonding pad 12 (as shown in FIG. 3A) and flows between the third part 12A of the first bonding pad 12 and the first part 21A of the second bonding pad 21. Thus, the first bonding pad 12 and the second bonding pad 21 are bonded through the bonding material 3 to achieve the purpose of assembling the substrates. The sealed space SP is formed between the mother substrate S1 and the second substrate 2. Since the third part 12A and the fourth part 12B of the first bonding pad 12 and the first part 21A and the second part 21B of the second bonding pad 21 respectively have close surrounding structures, after assembling the substrates, the vacuum effect in the sealed space SP can be enhanced, thereby improving the reliability of the electronic device.

In one embodiment of the present disclosure, FIG. 3C shows a cross-sectional view of the line A-A′ passing through the first connection portion 12C of the first bonding pad 12 and the line B-B′ not passing through the first connection portion 12C of the first bonding pad 12, wherein the bonding material 3 may be disposed between the third part 12A of the first bonding pad 12 and the first part 21A of the second bonding pad 21 and between the fourth part 12B of the first bonding pad 12 and the second part 21B of the second bonding pad 21. In addition, as shown in FIG. 3C, the bonding material 3 may also be disposed between the first connection portion 12C of the first bonding pad 12 and the second substrate 2.

In one embodiment of the present disclosure, as shown in FIG. 3C and FIG. 3D, in a cross-sectional view, the bonding material 3 may comprise curved or irregular surface. In the present disclosure, the distance D1 between the first edge e1 of the bonding material 3 and the first part 21A of the second bonding pad 21 may be less than the distance D2 between the second edge e2 of the bonding material 3 and the second part 21B of the second bonding pad 21. In one embodiment of the present disclosure, as shown in FIG. 3D, when the bonding material 3 comprises a curved or irregular surface, the “second edge e2” refers to the position 3b where the bonding material 3 contacts the first bonding pad 12 and is farthest from the sealed space SP in a cross section. In one embodiment of the present disclosure, as shown in FIG. 3D, the distance D1 between the first edge e1 of the bonding material 3 and the first part 21A of the second bonding pad 21 may be, for example, 0, so the distance D1 is not shown in FIG. 3D, but the present disclosure is not limited thereto. In other embodiments, the distance D1 may be greater than 0 and less than distance D2. The “distance D1” refers to, for example, the distance between the orthographic projection position 3a′ of the position 3a where the bonding material 3 contacts the first bonding pad 12 and closest to the sealed space SP on the mother substrate S1 (or the first substrate 1) and the orthographic projection position 21As1′ of the side 21As1 of the first part 21A of the second bonding pad 21 adjacent to the sealed space SP on the mother substrate S1 (or the first substrate 1) in a cross section. The “distance D2” refers to, for example, the distance between the orthographic projection position 3b′ of the position 3b where the bonding material 3 contacts the first bonding pad 12 and is farthest from the sealed space SP on the mother substrate S1 (or the first substrate 1) and the orthographic projection position 21Bs1′ of the side 21Bs1 of the second part 21B of the second bonding pad 21 that is farthest from the sealed space SP on the mother substrate S1 (or the first substrate 1) in a cross section.

Next, similar to that shown in FIG. 1D and FIG. 1E, the step of cutting the mother substrate S1 and the element layer 11 is performed to form a plurality of electronic devices. The details may be referred to the above and are not described again here.

In the present disclosure, the materials and other features of the mother substrate S1, the element layer 11, the first bonding pad 12, the second substrate 2, the second bonding pad 21 and the bonding material 3 may be as those described above, and are not described again here. In addition, the methods for forming the first bonding pad 12 and the second bonding pad 21, heating the bonding material 3 and cutting the mother substrate S1 and the element layer 11 can be referred to those described above, and are not described again here.

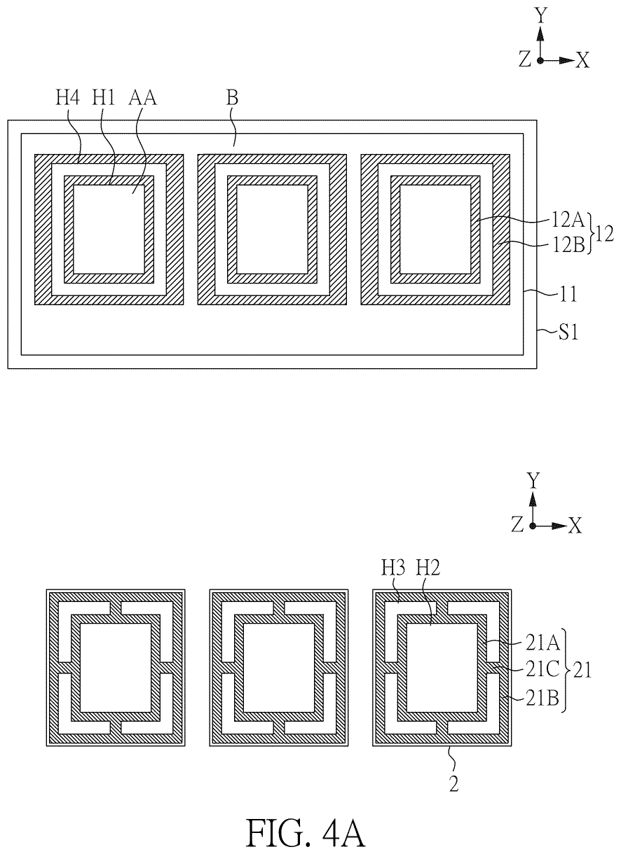

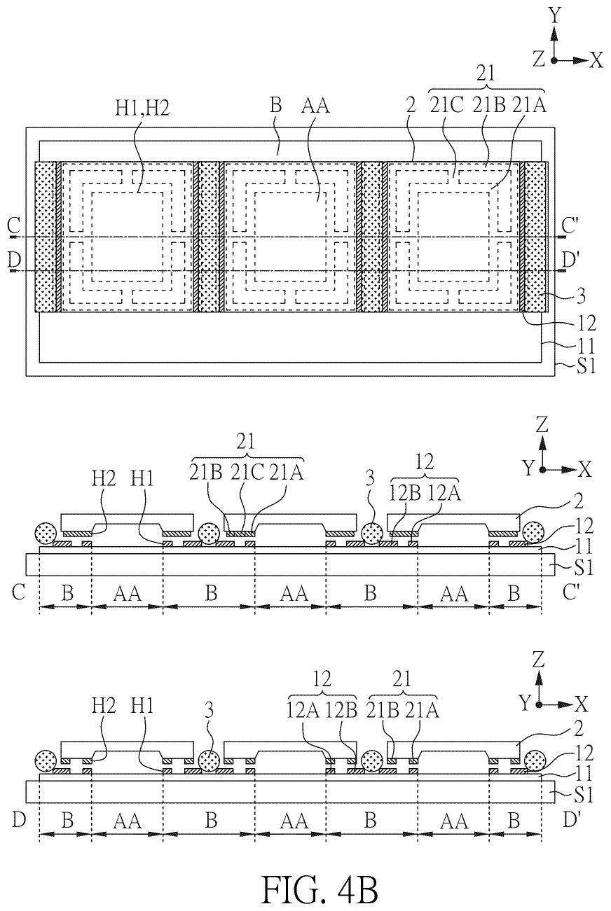

FIG. 4A and FIG. 4B are schematic views showing a method for manufacturing an electronic device according to one embodiment of the present disclosure. The upper view of FIG. 4A is a top schematic view of the mother substrate, and the lower view thereof is a top schematic view of the second substrate. The upper view of FIG. 4B is a top schematic view, and the middle and lower views thereof are cross-sectional schematic views. In addition, the manufacturing method shown in FIG. 4A and FIG. 4B is similar to those of FIG. 1A to FIG. 1E as well as FIG. 3A to FIG. 3C, and is not described again here.

In one embodiment of the present disclosure, as shown in FIG. 4A, the method for manufacturing an electronic device may comprise: providing a mother substrate S1; forming an element layer 11 on the mother substrate S1; forming a plurality of first bonding pads 12 on the peripheral area B of the element layer 11; providing a plurality of second substrates 2; and forming a plurality of second bonding pads 21 on the second substrates 2. Herein, the first bonding pad 12 comprises a third part 12A and a fourth part 12B surrounding the third part 12A. The second bonding pad 21 comprises a first part 21A, a second part 21B and a second connection portion 21C, the second part 21B surrounds the first part 21A, and the second connection portion 21C connects the first part 21A and the second part 21B respectively.

More specifically, as shown in FIG. 4A, in the top view direction Z, the third part 12A and the fourth part 12B of the first bonding pad 12 respectively form a close surrounding structure, wherein the third part 12A of the first bonding pad 12 comprises an opening H1, the fourth part 12B of the first bonding pad 12 comprises an opening H4, and the opening H1 exposes the active area AA of the element layer 11. In the top view direction Z, the projection area of the opening H1 on the mother substrate S1 may be approximately equal to the projection area of the active area AA on the mother substrate S1. The first part 21A and the second part 21B of the second bonding pad 21 are connected through the second connection portion 21C respectively. In the present embodiment, the first part 21A of the second bonding pad 21 may be connected to the second part 21B through four second connection portions 21C, but the present disclosure is not limited thereto. In other embodiments, the number of the second connection portions 21C may be adjusted according to the needs.

In one embodiment of the present disclosure, as shown in FIG. 4A, the opening H1 of the third part 12A of the first bonding pad 12 may be approximately equal to the opening H2 of the first part 21A of the second bonding pad 21, the opening H4 of the fourth part 12B of the first bonding pad 12 may be approximately equal to the opening H3 of the second part 21B of the second bonding pad 21. Thus, in the subsequent assembling step, in the top view direction Z, the third part 12A of the first bonding pad 12 and the first part 21A of the second bonding pad 21 may be approximately overlapped, and the fourth part 12B of the first bonding pad 12 and the second part 21B of the second bonding pad 21 may be approximately overlapped.

Next, as shown in FIG. 4B, the second substrate 2 is placed on the element layer 11, and the second bonding pad 21 and the first bonding pad 12 are overlapped; and a bonding material 3 is applied on two adjacent first bonding pads 12. More specifically, FIG. 4B respectively shown the cross-sectional views of the line C-C′ passing through the second connection portion 21C of the second bonding pad 21 and the line D-D′ not passing through the second connection portion 21C of the second bonding pad 21. As shown in FIG. 4A and FIG. 4B, when the second substrate 2 is placed on the element layer 11, in the top view direction Z, the first part 21A of the second bonding pad 21 and the third part 12A of the first bonding pad 12 are approximately overlapped, and the second part 21B of the second bonding pad 21 and the fourth part 12B of the first bonding pad 12 are approximately overlapped. In one embodiment of the present disclosure, the order of the steps placing the second substrate 2 on the element layer 11 and applying the bonding material 3 on two adjacent first bonding pads 12 are not particularly limited, may be adjusted according to the needs, and is not described again here.

In one embodiment of the present disclosure, as shown in FIG. 4B, the bonding material 3 may directly contact the fourth part 12B of the first bonding pad 12, but the present disclosure is not limited thereto. In other embodiments, the bonding material 3 may directly contact the fourth part 12B of the first bonding pad 12 and the element layer 11.

Next, similar to that shown in FIG. 3C, the method for manufacturing the electronic device may further comprise: heating the bonding material 3, wherein the bonding material 3 melts and diffuses between the first part 21A of the second bonding pad 21 and the third part 12A of the first bonding pad 12 and between the second part 21B of the second bonding pad 21 and the fourth part 12B of the first bonding pad 12. More specifically, since the first bonding pad 12 and/or the second bonding pad 21 has affinity with the bonding material 3, by heating the bonding material 3, the bonding material 3 melts into liquid or semi-liquid state and flows between the fourth part 12B of the first bonding pad 12 and the second part 21B of the second bonding pad 21. Next, the bonding material 3 may pass through the second connection portion 21C of the second bonding pad 21 (as shown in FIG. 4A) and flows between the third part 12A of the first bonding pad 12 and the first part 21A of the second bonding pad 21, so the first bonding pad 12 and the second bonding pad 21 are bonded through the bonding material 3 to achieve the purpose of assembling the substrates. Thus, the sealed space SP can be formed between the mother substrate S1 and the second substrate 2 (as shown in FIG. 3C). Since the third part 12A and the fourth part 12B of the first bonding pad 12 and the first part 21A and the second part 21B of the second bonding pad 21 respectively has a close surrounding structure, after assembling the substrates, the vacuum effect of the sealed space SP (as shown in FIG. 3C) can be enhanced, thereby improving the reliability of the electronic device.

In one embodiment of the present disclosure, even not shown in the figure, the bonding material 3 may be disposed between the third part 12A of the first bonding pad 12 and the first part 21A of the second bonding pad 21 and between the fourth part 12B of the first bonding pad 12 and the second part 21B of the second bonding pad 21. In addition, for example, referring to FIG. 3C, the bonding material 3 may also be disposed between the second connection portion 21C of the second bonding pad 21 (as shown in FIG. 4A) and the mother substrate S1.

Next, similar to that shown in FIG. 1D and FIG. 1E, the step of cutting the mother substrate S1 and the element layer 11 is performed to form a plurality of electronic devices. The details may be referred to the above and are not described again here.

In the present disclosure, the materials and other features of the mother substrate S1, the element layer 11, the first bonding pad 12, the second substrate 2, the second bonding pad 21 and the bonding material 3 may be as those described above and are not described again here. In addition, the methods for forming the first bonding pad 12 and the second bonding pad 21, heating the bonding material 3 and cutting the mother substrate S1 and the element layer 11 can be referred to those described above, and are not described again here.

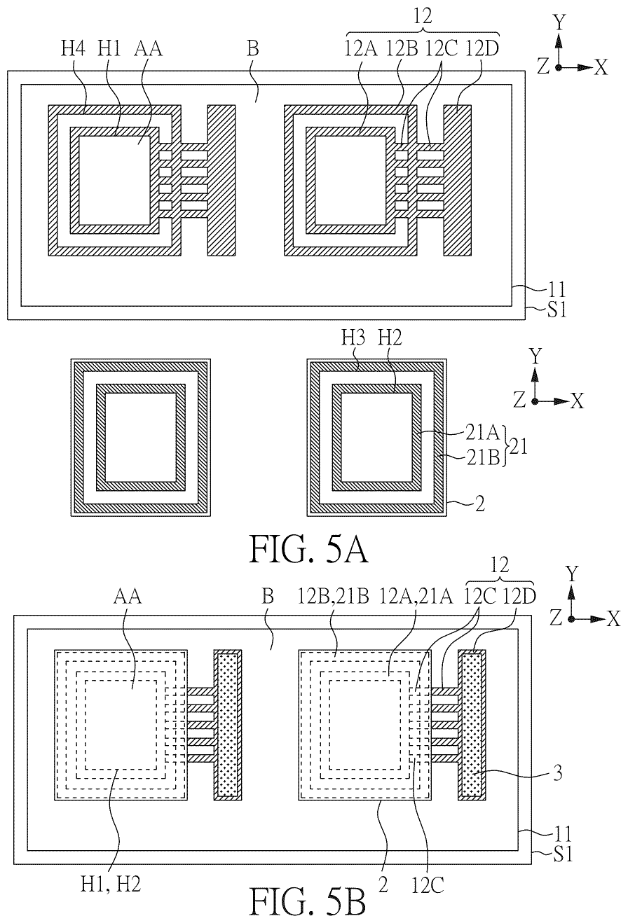

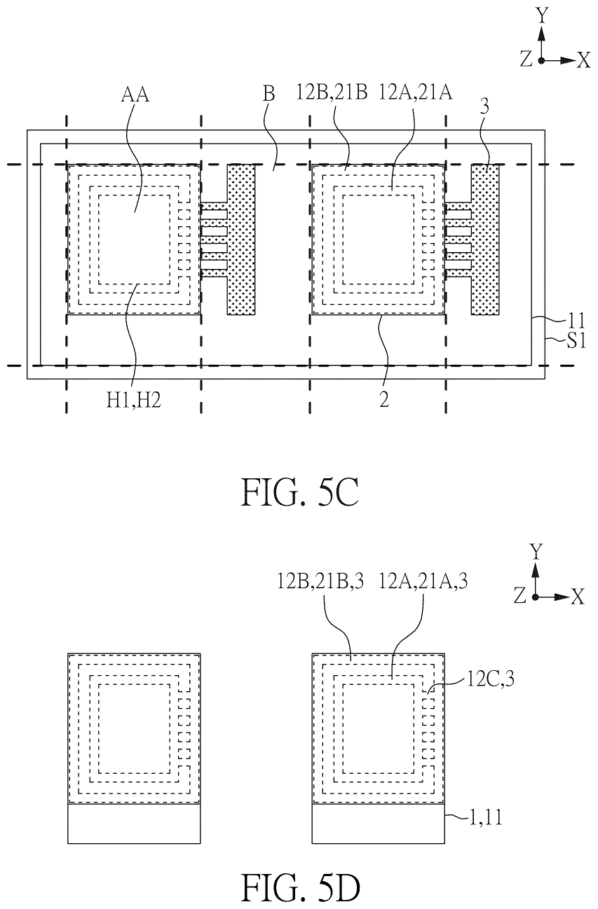

FIG. 5A to FIG. 5D are schematic views showing a method for manufacturing an electronic device according to one embodiment of the present disclosure. The upper view of FIG. 5A is a top schematic view of the mother substrate, and the lower view thereof is a top schematic view of the second substrate. In addition, the manufacturing method shown in FIG. 5A to FIG. 5D is similar to that shown in FIG. 1A to FIG. 1E, except for the following differences.

In one embodiment of the present disclosure, as shown in FIG. 5A, the method for manufacturing the electronic device may comprise: providing a mother substrate S1; forming an element layer 11 on the mother substrate S1; forming a plurality of first bonding pads 12 on the peripheral area B of the element layer 11; providing a plurality of second substrates 2; and forming a plurality of second bonding pads 21 on the second substrates 2. Herein, the first bonding pad 12 comprises a third part 12A, a fourth part 12B, a first connection portion 12C and a carrier portion 12D, the fourth part 12B surrounds the third part 12A, the carrier portion 12D is disposed at one side of the fourth part 12B, and the first connection portion 12C connects the third part 12A, the fourth part 12B and the carrier portion 12D respectively. The second bonding pad 21 comprises a first part 21A and a second part 21B surrounding the first part 21A.

More specifically, as shown in FIG. 5A, in the top view direction Z, the third part 12A and the fourth part 12B of the first bonding pad 12 respectively form a close surrounding structure, the carrier portion 12D of the first bonding pad 12 is disposed at one side of the fourth part 12B, and the carrier portion 12D is connected to two surrounding structures through the first connection portion 12C respectively. For example, the carrier portion 12D is connected to the third part 12A and the fourth part 12B through the first connection portion 12C, but the present disclosure is not limited thereto. The third part 12A of the first bonding pad 12 comprises an opening H1, the fourth part 12B of the first bonding pad 12 comprises an opening H4, and the opening H1 exposes the active area AA of the element layer 11. In the top view direction Z, the projection area of the opening H1 on the mother substrate S1 may be approximately equal to the projection area of the active area AA on the mother substrate S1. In addition, in the present embodiment, the carrier portion 12D of the first bonding pad 12 may be connected to the fourth part 12B through, for example, a plurality of first connection portions 12C, and the fourth part 12B may be connected to the third part 12A through, for example, a plurality of first connection portions 12C, but the present disclosure is not limited thereto. In other embodiments, the number of the first connection portions 12C may be adjusted according to the needs. In the present embodiment, the first connection portions 12C may respectively connect the carrier portion 12D and fourth part 12B as well as connect the third part 12A and the fourth part 12B. More specifically, the first connection portion 12C may be disposed between the carrier portion 12D and the fourth part 12B, and the carrier portion 12D and the fourth part 12B are connected through the first connection portion 12C. The first connection portion 12C may be disposed between the third part 12A and the fourth part 12B, and the third part 12A and the fourth part 12B are connected through the first connection portion 12C. In one embodiment of the present disclosure, a part of the fourth part 12B may be disposed between a plurality of first connection portions 12C. In one embodiment of the present disclosure, the first connection portion 12C may extend along one direction (for example, the X direction), and the fourth part 12B connecting the first connection portion 12C may extend along another direction (for example, the Y direction), wherein the one direction (for example, the X direction) is different from the another direction (for example, the Y direction).

In one embodiment of the present disclosure, as shown in FIG. 5A, the opening H1 of the third part 12A of the first bonding pad 12 may be approximately equal to the opening H2 of the first part 21A of the second bonding pad 21, and the opening H4 of the fourth part 12B of the first bonding pad 12 may be approximately equal to the opening H3 of the second part 21B of the second bonding pad 21. Thus, in the subsequent assembling steps, in the top view direction Z, the third part 12A of the first bonding pad 12 and the first part 21A of the second bonding pad 21 may be approximately overlapped, and the fourth part 12B of the first bonding pad 12 and the second part 21B of the second bonding pad 21 may be approximately overlapped.

Next, as shown in FIG. 5B, the second substrate 2 is placed on the element layer 11 to make the second bonding pad 21 and first bonding pad 12 overlapped, and a bonding material 3 is applied on the carrier portion 12D of the first bonding pad 12. More specifically, as shown in FIG. 5A and FIG. 5B, the second substrate 2 is placed on the element layer 11, and the first part 21A of the second bonding pad 21 and the third part 12A of the first bonding pad 12 are approximately overlapped as well as the second part 21B of the second bonding pad 21 and the fourth part 12B of the first bonding pad 12 are approximately overlapped in the top view direction Z. In one embodiment of the present disclosure, the order of the steps of placing the second substrate 2 on the element layer 11 and applying the bonding material 3 on the carrier portion 12D of the first bonding pad 12 is not particularly limited, may be adjusted according to the needs and is not described again here.

Next, as shown in FIG. 5A and FIG. 5C, the bonding material 3 is heated, so the bonding material 3 melts and diffuses between the first part 21A of the second bonding pad 21 and the third part 12A of the first bonding pad 12 and between the second part 21B of the second bonding pad 21 and the fourth part 12B of the first bonding pad 12. More specifically, as shown in FIG. 5A and FIG. 5C, since the first bonding pad 12 and/or the second bonding pad 21 has affinity with the bonding material 3, after heating the bonding material 3, the bonding material 3 melts into liquid or semi-liquid state, the bonding material 3 may flow from the carrier portion 12D of the first bonding pad 12 to the first connection portion 12C, and flow through the first connection portion 12C to between the fourth part 12B of the first bonding pad 12 and the second part 21B of the second bonding pad 21. Next, the bonding material 3 flows through a part of the first connection portion 12C into between the third part 12A of the first bonding pad 12 and the first part 21A of the second bonding pad 21. Thus, the first bonding pad 12 and the second bonding pad 21 are bonded through the bonding material 3, thereby achieving the purpose of assembling the mother substrate S1 and the second substrate 2.

Next, as shown in FIG. 5C and FIG. 5D, the mother substrate S1 and the element layer 11 are cut to form a plurality of electronic devices. More specifically, the bonding material 3, the first bonding pad 12, the element layer 11 and the mother substrate S1 are respectively cut along the dash line in FIG. 5C, thereby forming a plurality of electronic device with suitable size, as shown in FIG. 5D. Herein, the mother substrate S1 is cut into the first substrate 1. In the present embodiment, the cutting is according to the dash line in FIG. 5C approximately along the edge of a part of the element layer 11 and the size of the second substrate 2. Thus, as shown in FIG. 5D, the projection area of the cut element layer 11 of the electronic device may be approximately equal to the projection area of the first substrate 1. However, in other embodiments of the present disclosure, the projection area of the first substrate 1 of the electronic device may be greater than the projection area of the cut element layer 11.

In the present disclosure, the materials and other features of the mother substrate S1, the element layer 11, the first bonding pad 12, the second substrate 2, the second bonding pad 21 and the bonding material 3 are as those described above, and are not described again here. In addition, the methods for forming the first bonding pad 12 and the second bonding pad 21, heating the bonding material 3 and cutting the mother substrate S1 and the element layer 11 can be referred to the above and are not described again here.

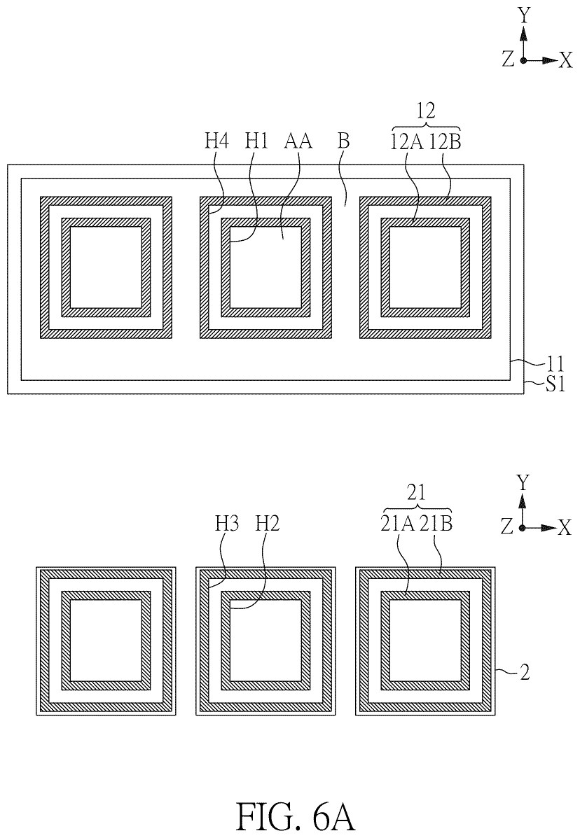

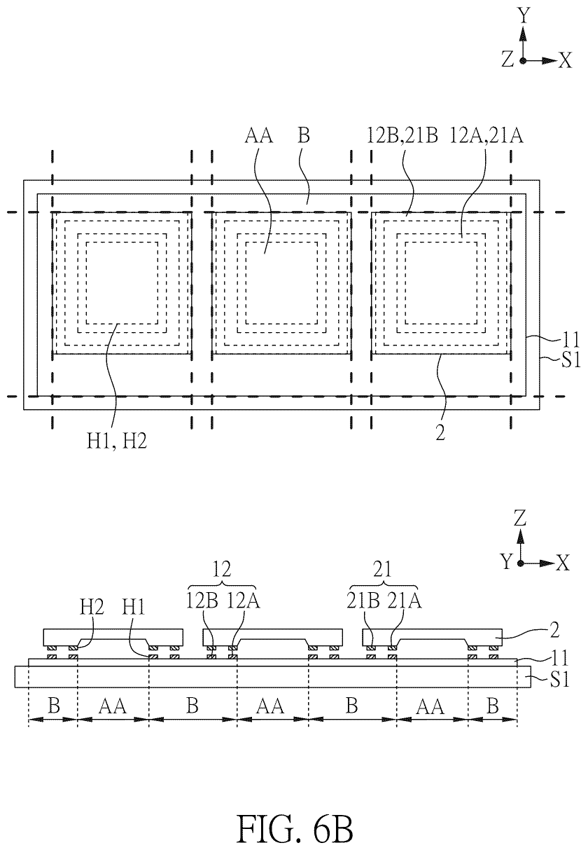

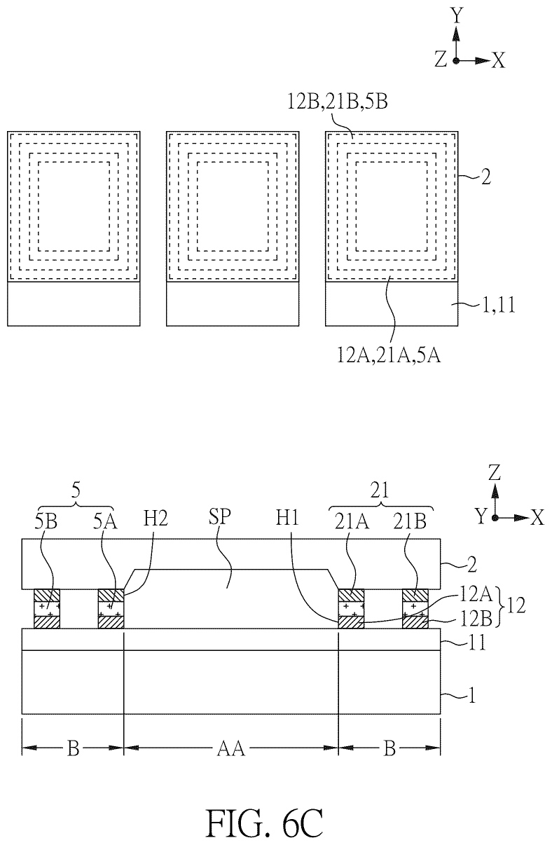

FIG. 6A to FIG. 6C are schematic views showing a method for manufacturing an electronic device according to one embodiment of the present disclosure. Herein, the upper view of FIG. 6A is top schematic view of the mother substrate and the lower view is a top schematic view of the second substrate. The upper views of FIG. 6B and FIG. 6C are top schematic views and the lower views thereof are cross-sectional schematic views. In addition, the manufacturing methods shown in FIG. 6A to FIG. 6C are similar to that shown in FIG. 1A to FIG. 1E, except for the following differences.

In one embodiment of the present disclosure, as shown in FIG. 6A, the method for manufacturing the electronic device may comprise: providing a mother substrate S1; forming an element layer 11 on the mother substrate S1; forming a plurality of first bonding pads 12 on the peripheral area B of the element layer 11; providing a plurality of second substrates 2; and forming a plurality of second bonding pads 21 on the second substrates 2. Herein, the first bonding pad 12 comprises a third part 12A and a fourth part 12B surrounding the third part 12A. The second bonding pad 21 comprises a first part 21A and a second part 21B surrounding the first part 21A.

More specifically, as shown in FIG. 6A, in the top view direction Z, the third part 12A and the fourth part 12B of the first bonding pad 12 respectively form a close surrounding structure, wherein the third part 12A of the first bonding pad 12 comprises an opening H1, the fourth part 12B of the first bonding pad 12 comprises an opening H4, and the opening H1 exposes the active area AA of the element layer 11. In top view direction Z, the projection area of the opening H1 on the mother substrate S1 may be approximately equal to the projection area of the active area AA on the mother substrate S1. The first part 21A and the second part 21B of the second bonding pad 21 respectively form a close surrounding structure, wherein the first part 21A of the second bonding pad 21 comprise an opening H2, and the second part 21B of the second bonding pad 21 comprises an opening H3. In the top view direction Z, the projection area of the opening H2 on the second substrate 2 may be approximately equal to the projection area of the active area AA on the mother substrate S1.

Next, as shown in FIG. 6B, the second substrate 2 is placed on the element layer 11 to make the second bonding pad 21 and the first bonding pad 12 overlapped. More specifically, in the top view direction Z, the first part 21A of the second bonding pad 21 and the third part 12A of the first bonding pad 12 are approximately overlapped, and the second part 21B of the second bonding pad 21 and the fourth part 12B of the first bonding pad 12 are approximately overlapped. At this time, in the top view direction Z, the opening H1 of the third part 21A of the first bonding pad 12 and the opening H2 of the first part 21A of the second bonding pad 21 are overlapped.

Next, as shown in FIG. 6B and FIG. 6C, the mother substrate S1 and the second substrate 2 are assembled to bond the mother substrate S1 and the second substrate 2; and the mother substrate S1 and the element layer 11 are cut to form a plurality of electronic devices. As shown in FIG. 6C, the mother substrate S1 is cut into the first substrate 1. By performing a bonding process on the first bonding pad 12 and the second bonding pad 21, a bonding member 5 is formed between the first bonding pad 12 and the second bonding pad 21, thereby bonding the mother substrate S1 and the second substrate 2 to form a sealed space SP. More specifically, the first part 5A of the bonding member 5 is formed between the third part 12A of the first bonding pad 12 and the first part 21A of the second bonding pad 21, and the second part 5B of the bonding member 5 is formed between the fourth part 12B of the first bonding pad 12 and the second part 21B of the second bonding pad 21, thereby bonding the third part 12A of the first bonding pad 12 and the first part 21A and the second bonding pad 21 as well as bonding the fourth part 12B of the first bonding pad 12 and the second part 21B of the second bonding pad 21.

In the present disclosure, the materials and other features of the mother substrate S1, the element layer 11, the first bonding pad 12, the second substrate 2 and the second bonding pad 21 may be referred to those described above and are not described again here. In addition, the methods for forming the first bonding pad 12 and the second bonding pad 21 and cutting the mother substrate S1 and the element layer 11 may be referred to those described above, and are not described again here. In the present disclosure, the bonding member 5 may comprise a compound produced by a chemical reaction between a portion of the first bonding pad 12 and a portion of the second bonding pad 21. For example, the bonding member 5 may comprise a eutectic compound of the first bonding pad 12 and the second bonding pad 21. Therefore, the material of the bonding member 5 may be different from that of the first bonding pad 12 and the second bonding pad 21, but the present disclosure is not limited thereto. In the present disclosure, the assembling includes heating and applying pressure to bring the second substrate 2 and the mother substrate S1 close to each other. In the present disclosure, the bonding process may include thermocompression bonding, eutectic bonding, laser welding, other suitable processes or a combination thereof. In the present disclosure, the bonding process includes heating, applying pressure or a combination thereof to the first bonding pad 12 and the second bonding pad 21 to achieve the purpose of bonding the mother substrate S1 and the second substrate 2 to form a sealed space SP.

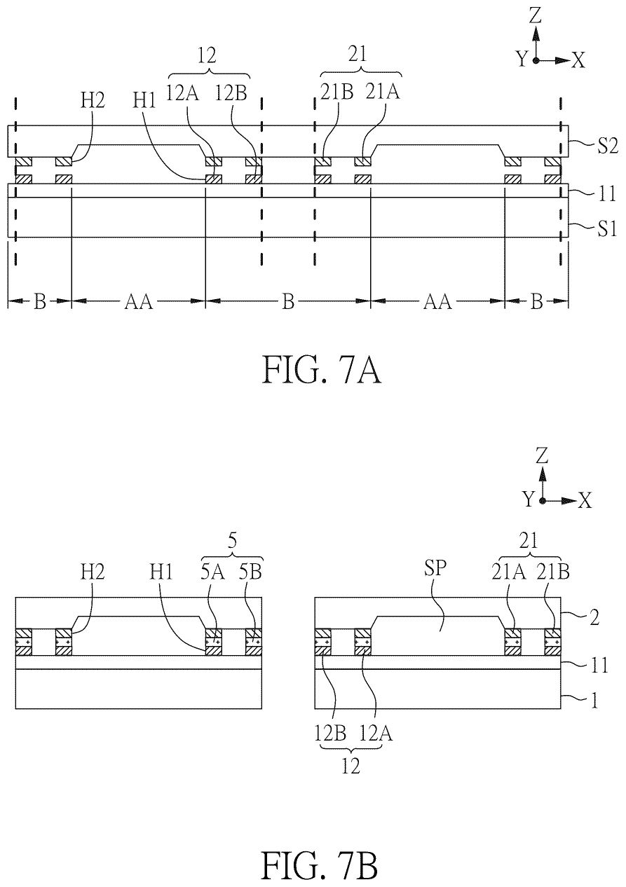

FIG. 7A and FIG. 7B are schematic views showing a method for manufacturing an electronic device according to one embodiment of the present disclosure. The manufacturing method shown in FIG. 7A and FIG. 7B is similar to that shown in FIG. 6A to FIG. 6C, except for the following differences.

In one embodiment of the present disclosure, as shown in FIG. 6A and FIG. 7A, the method for manufacturing the electronic device may comprise: providing a mother substrate S1; forming an element layer 11 on the mother substrate S1; forming a plurality of first bonding pads 12 on the peripheral area B of the element layer 11; providing a second mother substrate S2; and forming a plurality of second bonding pad 21 on the second mother substrate S2. Herein, the first bonding pad 12 comprises a third part 12A and a fourth part 12B surrounding the third part 12A. The second bonding pad 21 comprises a first part 21A and a second part 21B surrounding the first part 21A.

Then, as shown in FIG. 7A, the second mother substrate S2 is placed on the element layer 11 to make the second bonding pad 21 and the first bonding pad 12 overlapped. At this time, in the top view direction Z, the opening H1 of the third part 21A of the first bonding pad 12 and the opening H2 of the first part 21A of the second bonding pad 21 may be approximately overlapped. Then, the mother substrate S1 and the second mother substrate S2 are assembled to bond the mother substrate S1 and the second mother substrate S2; and the mother substrate S1, the second mother substrate S2 and the element layer 11 are cut to form a plurality of electronic devices, as shown in FIG. 7B. Herein, the mother substrate S1 is cut into the first substrate 1, and the second mother substrate S2 is cut into the second substrate 2. By performing a bonding process on the first bonding pad 12 and the second bonding pad 21, a bonding member 5 is formed between the first bonding pad 12 and the second bonding pad 21, thereby bonding the mother substrate S1 and the second substrate 2 to form a sealed space SP.

In the present disclosure, the materials and other features of the mother substrate S1, the element layer 11, the first bonding pad 12, the second substrate 2, the second bonding pad 21 and the bonding member 5 may be referred to those described above and are not described again here. In addition, the method for forming the first bonding pad 12 and the second bonding pad 21, cutting the mother substrate S1, the second mother substrate S2 and the element layer 11 and bonding may be referred to those described above, and are not described again here.

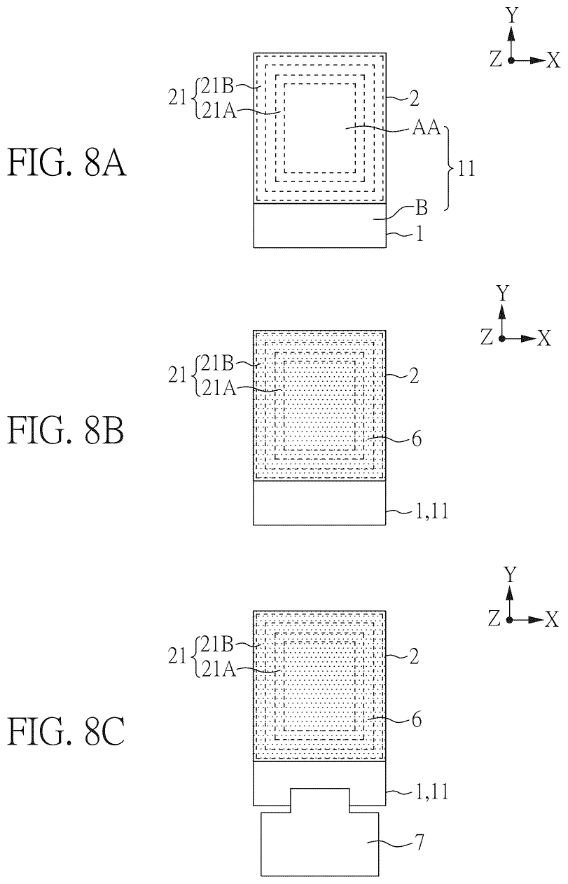

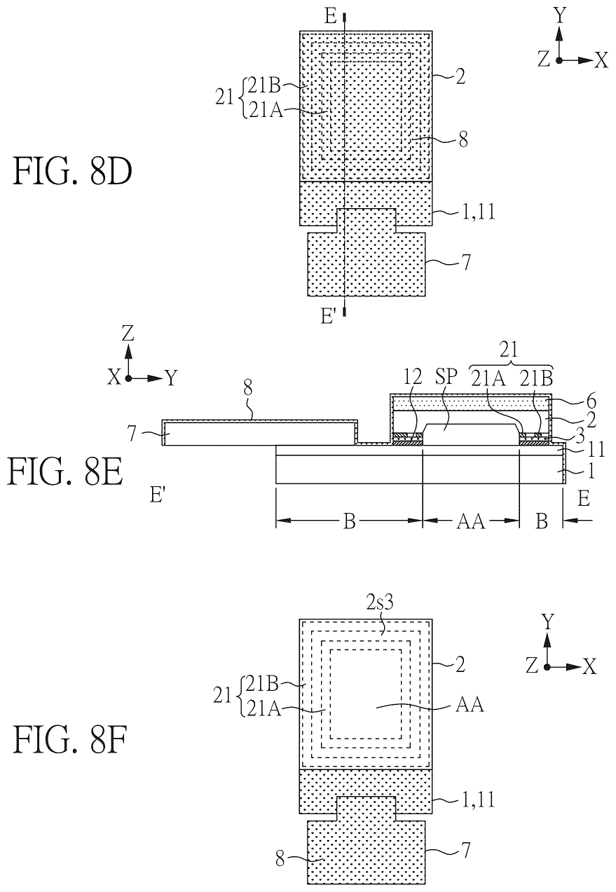

FIG. 8A to FIG. 8F are schematic views showing a method for manufacturing an electronic device according to one embodiment of the present disclosure. Herein, FIG. 8E is a cross-sectional view of the line E-E′ in FIG. 8D.

In one embodiment of the present disclosure, as shown in FIG. 8A to FIG. 8B, the method for manufacturing the electronic device may further comprise: attaching a peelable glue 6 on the second substrate 2. Herein, the electronic device of FIG. 1E is used as an example in FIG. 8A. However, in other embodiments of the present disclosure, the electronic device of FIG. 8A may be any of the aforesaid electronic devices. Then, as shown in FIG. 8C, a circuit board 7 is disposed on the first substrate 1. More specifically, the circuit board 7 is disposed on the peripheral area B of the element layer 11, and electrically connected to elements in the active area AA of the element layer 11 through a circuit (not shown in the figure).

In the present disclosure, the peelable glue 6 may comprise a release layer, UV peelable glue, thermosetting peelable glue or a combination thereof, but the present disclosure is not limited thereto. In the present disclosure, the circuit board 7 may comprise a rigid circuit board or a flexible circuit board, for example, a printed circuit board (PCB) or a flexible printed circuit (FPC), but the present disclosure is not limited thereto.

Next, as shown in FIG. 8D and FIG. 8E, a protection film 8 is formed on the electronic device and the circuit board 7. More specifically, the protection film 8 may be formed on the element layer 11, the peelable glue 6 and the circuit board 7, and formed on side walls of the first substrate 1, the element layer 11, the first bonding pad 12, the second substrate 2, the second bonding pad 21, the bonding material 3, the peelable glue 6 and the circuit board 7. The protection film 8 can be used to prevent outside air or moisture from entering the electronic device through the joints between components, thereby improving the reliability of the electronic device.

In the present disclosure, the material of the protection film 8 may comprise glass glue, optical glue, silicone glue, hot melt glue, AB glue, light curing glue, polymer glue, resin, poly-para-xylylene (parylene) or a combination thereof, but the present disclosure is not limited thereto. In the present disclosure, any suitable method may be used to form the protection film 8, such as dip coating, spin coating, roller coating, blade coating, spray coating, deposition or a combination thereof, but the present disclosure is not limited thereto.

Next, as shown in FIG. 8F, the peelable glue 6 and the protection film 8 on the peelable glue 6 are removed. More specifically, in the top view direction Z, the protection film 8 may be overlapped with the circuit board 7, a part of the first substrate 1 and a part of the element layer 11, and the protection film 8 is not overlapped with the upper surface 2s3 of the second substrate 2 (which is equivalent to the side 2s2 of the second substrate 2 away from the first substrate 1 shown in FIG. 2). Thus, the elements in the active area AA of the element layer 11 are not affected by the protection film 8. For example, the active area AA of the element layer 11 may comprise a sensing unit (not shown in the figure). Since the protection film 8 and the active area AA of the element layer 11 are not overlapped in the top view direction Z, the interference on the sensing signal can be reduced.

In the present disclosure, the method of removing the peelable glue 6 may be, for example, removing the peelable glue 6 by applying an external force to the peelable glue 6. The “external force” may include physical, chemical or optical external forces or stress, such as heating, laser, ultraviolet light, mechanical force, or a combination thereof, but the present disclosure is not limited thereto.

After the steps of FIG. 8A to FIG. 8F above, the electronic device may further comprise: a circuit board 7 disposed on the first substrate 1 and electrically connected to the element layer 11; and a protection film 8 disposed on the circuit board 7 and a part of the first substrate 1, wherein the protection film 8 and the second substrate 2 are not overlapped in the top view direction Z.

In the present disclosure, by providing the first bonding pad 12 and the second bonding pad 21 to perform substrate assembling, the vacuum effect of the sealed space SP of the electronic device can be increased, thereby improving the reliability and/or packaging fault tolerance of the electronic device.

The above specific embodiments should be construed as merely illustrative, and not limitative of the remainder of the disclosure in any way.

Although the present disclosure has been explained in relation to its embodiment, it is to be understood that many other possible modifications and variations can be made without departing from the spirit and scope of the disclosure as hereinafter claimed.

1. An electronic device, comprising:
a first substrate;
an element layer disposed on the first substrate and comprising an active area and a peripheral area surrounding the active area;
a first bonding pad disposed on the peripheral area of the element layer;
a second substrate disposed opposite to the first substrate;
a second bonding pad disposed on the second substrate and comprising a first part and a second part surrounding the first part; and
a bonding material disposed between the first part of the second bonding pad and the first bonding pad and between the second part of the second bonding pad and the first bonding pad.

2. The electronic device of claim 1, wherein the bonding material has a first edge and a second edge, the first edge is adjacent to the active area, and the second edge is opposite to the first edge, wherein a distance between the first edge and the first part is less than a distance between the second edge and the second part.

3. The electronic device of claim 1, wherein the first bonding pad comprises a third part and a fourth part surrounding the third part, wherein the bonding material is disposed between the third part of the first bonding pad and the first part of the second bonding pad and between the fourth part of the first bonding pad and the second part of the second bonding pad.

4. The electronic device of claim 3, wherein the first bonding pad comprises a first connection portion respectively connecting to the third part and the fourth part.

5. The electronic device of claim 1, wherein the second bonding pad comprises a second connection portion respectively connecting to the first part and the second part.

6. The electronic device of claim 1, wherein the second substrate comprises a first region and a second region surrounding to the first region, the first region and the active area are overlapped in a top view direction of the first substrate, and a thickness of at least part of the first region of the second substrate is less than a thickness of the second region of the second substrate.

7. The electronic device of claim 1, wherein the active area comprises a plurality of sensing units.

8. The electronic device of claim 1, wherein the first bonding pad comprises a gold layer, and a thickness of the gold layer ranges from 0.4 μm to 10 μm.

9. The electronic device of claim 1, wherein the first bonding pad comprises a palladium layer, and a thickness of the palladium layer ranges from 0.1 m to 5 μm.

10. The electronic device of claim 1, wherein a thickness of the first bonding pad is 0.1 μm to 35 μm.

11. The electronic device of claim 1, wherein a thickness of the second bonding pad is 0.1 μm to 35 μm.

12. A method for manufacturing an electronic device, comprising the following steps:
providing a mother substrate;
forming an element layer on the mother substrate, wherein the element layer comprises a plurality of active areas and a peripheral area surrounding the plurality of active areas;
forming a plurality of first bonding pads on the peripheral area of the element layer;
providing a plurality of second substrates;
forming a plurality of second bonding pads on the plurality of second substrates, wherein each of the plurality of second bonding pads respectively comprises a first part and a second part surrounding the first part;
disposing the plurality of second substrates on the element layer to make the plurality of second bonding pads and the plurality of first bonding pads overlapped, and applying a bonding material on two adjacent first bonding pads of the plurality of the first bonding pads; and
heating the bonding material, wherein the bonding material melts and diffuses between the first parts of the plurality of the second bonding pads and the plurality of first bonding pads and between the second parts of the plurality of second bonding pads and the plurality of first bonding pads.

13. The method of claim 12, further comprising a step of: cutting the mother substrate and the element layer to form a plurality of electronic devices, wherein one of the plurality of electronic devices comprises:
a first substrate formed by cutting the mother substrate;
the element layer disposed on the first substrate;
one of the plurality of first bonding pads disposed on the peripheral area of the element layer;
one of the plurality of second substrates disposed opposite to the first substrate;
one of the plurality of the second bonding pads disposed on the one of the plurality of second substrates, wherein the one of the plurality of second bonding pads comprises the first part and the second part surrounding the first part; and
the bonding material disposed between the first part of the one of the plurality of second bonding pads and the one of the plurality of the first bonding pads and between the second part of the one of the plurality of the second bonding pads and the one of the plurality of the first bonding pads.

14. The method of claim 13, further comprising the following step:
attaching a peelable glue on the one of the plurality of second substrates;
disposing a circuit board on the first substrate;
forming a protection film on the electronic device and the circuit board; and
removing the peelable glue and the protection film on the peelable glue.

15. The method of claim 13, wherein bonding material has a first edge and a second edge, the first edge is adjacent to one of the plurality of active areas, and the second edge is opposite to the first edge, wherein a distance between the first edge and the first part is less than a distance between the second edge and the second part.

16. The method of claim 13, wherein the one of the plurality of first bonding pads comprises a third part and a fourth part surrounding the third part, wherein the bonding material is disposed between the third part of the one of the plurality of first bonding pads and the first part of the one of the plurality of the second bonding pads and between the fourth part of the one of the plurality of first bonding pads and the second part of the one of the plurality of the second bonding pads.

17. The method of claim 16, wherein the one of the plurality of first bonding pads comprises a first connection portion respectively connecting to the third part and the fourth part.

18. The method of claim 13, wherein the one of the plurality of the second bonding pads comprises a second connection portion respectively connecting to the first part and the second part.

19. The method of claim 13, wherein the one of the plurality of second substrates comprises a first region and a second region surrounding to the first region, the first region and one of the plurality of active areas are overlapped in a top view direction of the first substrate, and a thickness of at least part of the first region of the one of the plurality of second substrates is less than a thickness of the second region of the one of the plurality of second substrates.

20. The method of claim 13, wherein one of the plurality of active areas comprises a plurality of sensing units.
